(19) United States
(12) Patent Application Publication
(10) Pub. No.: US 2026/0313656 A1
(43) Pub. Date: Oct. 8, 2026

(54) METHOD AND APPARATUS FOR SECONDARY CELL DORMANCY INDICATION

(71) Applicant: LENOVO (BEIJING) LIMITED, Beijing (CN)

(72) Inventor: Haipeng LEI, Beijing (CN)

(21) Appl. No.: 19/476,971

(22) PCT Filed: Nov. 2, 2023
(86) PCT No.: PCT/CN2023/129365

§ 371 Date: Oct. 20, 2025

(51) Int. Cl. H04W 72/231; H03M 13/09; H04L 1/1812; H04W 72/0453; H04W 72/0457; H04W 72/12

(52) U.S. Cl. CPC H04W 72/231; H03M 13/09; H04L 1/1812; H04W 72/0453; H04W 72/0457; H04W 72/12

(57) ABSTRACT

Embodiments of the present disclosure relate to method and apparatus for secondary cell dormancy indication. According to some embodiments of the disclosure, a UE may: receive, from a BS, a signaling configuring a first set of cells for multi-cell scheduling by a DCI format and CRC of the DCI format is scrambled by a C-RNTI or an MCS-C-RNTI of the UE; receive the DCI format from the BS; determine whether a set of fields in the DCI format is repurposed for indicating secondary cell dormancy for each secondary cell of the UE, wherein a first bit of the set of fields corresponds to a first secondary cell of the UE; and switch to a dormant BWP of the first secondary cell of the UE in response to the first bit indicating dormancy for the first secondary cell.

### TECHNICAL FIELD

Embodiments of the present disclosure generally relate to wireless communication technology, and more particularly to secondary cell (SCell) dormancy indication for multiple SCells by downlink control information (DCI).

### BACKGROUND

A wireless communication system may include one or multiple network communication devices, such as base stations, which may support wireless communication for one or multiple user communication devices, which may be otherwise known as user equipment (UE), or other suitable terminology. The wireless communication system may support wireless communication with one or multiple user communication devices by utilizing resources of the wireless communication system (e.g., time resources (e.g., symbols, slots, subframes, frames, or the like)) or frequency resources (e.g., subcarriers, carriers, or the like). Additionally, the wireless communication system may support wireless communication across various radio access technologies including third generation (3G) radio access technology, fourth generation (4G) radio access technology, fifth generation (5G) (which is also known as new radio (NR)) radio access technology, among other suitable radio access technologies beyond 5G (e.g., sixth generation (6G)).

Carrier aggregation (CA) technology may be used in a wireless communication system to, for example, increase data rates. For example, CA technology may refer to aggregating spectrum resources (e.g., carriers or cells) from the same frequency band or different frequency bands. In a CA scenario, multiple cells may be configured for a UE and DL or UL channels may be carried on one or more of the multiple cells.

A UE in a wireless communication system can be configured with one or more SCells. However, one or more of the configured SCells may not always be used for data transmission. Hence, power consumption can be reduced if the UE can stop monitoring physical downlink control channel (PDCCH) in one or more SCells where no data transmission is not expected.

There is a need for indication SCell dormancy in a wireless communication system.

### SUMMARY

An article “a” before an element is unrestricted and understood to refer to “at least one” of those elements or “one or more” of those elements. The terms “a,” “at least one,” “one or more,” and “at least one of one or more” may be interchangeable. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.” Further, as used herein, including in the claims, a “set” may include one or more elements.

Some embodiments of the present disclosure provide a UE. The UE may include at least one memory; and at least one processor coupled with the at least one memory and configured to cause the UE to: receive, from a base station (BS), a signaling configuring a first set of cells for multi-cell scheduling by a DCI format and cyclic redundancy check (CRC) of the DCI format is scrambled by a cell-radio network temporary identifier (C-RNTI) or a modulation and coding scheme C-RNTI (MCS-C-RNTI) of the UE; receive the DCI format from the BS; determine whether a set of fields in the DCI format is repurposed for indicating secondary cell dormancy for each secondary cell of the UE, wherein a first bit of the set of fields corresponds to a first secondary cell of the UE; and switch to a dormant bandwidth part (BWP) of the first secondary cell of the UE in response to the first bit indicating dormancy for the first secondary cell.

In some embodiments, the at least one processor is configured to cause the UE to: in response to a one-shot hybrid automatic repeat request acknowledgement (HARQ-ACK) request field being absent from the DCI format or indicating that one-shot HARQ-ACK feedback is not triggered, a HARQ-ACK retransmission indicator being absent from the DCI format or indicating that HARQ-ACK retransmission is not triggered, and all frequency domain resource assignment (FDRA) fields in the DCI format indicating invalid value, determine that the set of fields in the DCI format is repurposed for indicating secondary cell dormancy for each secondary cell of the UE.

In some embodiments, the DCI may include a first indicator indicating whether the set of fields in the DCI format is repurposed for indicating secondary cell dormancy for each secondary cell of the UE, or a second indicator in the DCI format is used for indicating secondary cell dormancy for each secondary cell group of the UE.

In some embodiments, in the case that the first indicator indicates the set of fields in the DCI format being repurposed for indicating secondary cell dormancy for each secondary cell of the UE, the DCI format does not schedule any data transmission. In some embodiments, in the case that the first indicator indicates the second indicator in the DCI format being used for indicating secondary cell dormancy for each secondary cell group of the UE, the DCI format schedules one or more data transmissions for the UE.

In some embodiments, the set of fields may include one or more FDRA fields corresponding to one or more cells with smallest serving cell indices among a second set of cells. In some embodiments, the second set of cells is indicated by the DCI format among the first set of cells in response to the DCI format including an indicator indicating scheduled cells, otherwise the second set of cells is the first set of cells.

In some embodiments, the first set of cells may include a primary cell of the UE. The at least one processor is configured to cause the UE to: in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and all FDRA fields in the DCI format except a FDRA field for the primary cell indicating invalid value, determine that the set of fields in the DCI format is repurposed for indicating secondary cell dormancy for each secondary cell of the UE.

In some embodiments, the set of fields does not include a field used for the primary cell.

In some embodiments, the at least one processor is further configured to cause the UE to determine whether the primary cell is scheduled by the DCI format based on whether the FDRA field for the primary cell indicates a valid value or invalid value or based on whether a scheduled cell combination indicated by the DCI format includes the primary cell or not.

In some embodiments, the at least one processor is configured to cause the UE to: in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and at least one FDRA field in the DCI format indicating an invalid value, determine that the set of fields in the DCI format is repurposed for indicating secondary cell dormancy for each secondary cell of the UE.

In some embodiments, the number of the at least one FDRA field is determined based on a number of secondary cells configured for the UE.

In some embodiments, the set of fields is specifically used for a cell with a smallest serving cell index among one or more cells within a second set of cells with corresponding FDRA fields in the DCI format indicating invalid value. In some embodiments, the second set of cells is indicated by the DCI format among the first set of cells in response to the DCI format including an indicator indicating scheduled cells, otherwise the second set of cells is the first set of cells.

In some embodiments, the set of fields are concatenated into a bitmap based indicator according to a predefined rule, and each secondary cell of the UE corresponds to a respective bit in the bitmap based indicator.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE.

In some embodiments, a first value of the first bit may indicate the UE to switch to the dormant BWP of the first secondary cell. In some embodiments, a second value of the first bit may indicate the UE to switch to a first active BWP of the first secondary cell in the case that current active BWP of the first secondary cell is the dormant BWP or may indicate the UE to maintain the current active BWP of the first secondary cell in the case that the current active BWP of the first secondary cell is not the dormant BWP.

In some embodiments, the set of fields may include one or more of the following: a cell-specific field with non-configurable field size; a cell-specific field with configurable field size; and a cell-common field.

Some embodiments of the present disclosure provide a BS. The BS may include at least one memory; and at least one processor coupled with the at least one memory and configured to cause the BS to: transmit, to a UE, a signaling configuring a first set of cells for multi-cell scheduling by a DCI format and CRC of the DCI format is scrambled by a C-RNTI or an MCS-C-RNTI of the UE; and transmit the DCI format to the UE, wherein the DCI format may indicate whether a set of fields in the DCI format is repurposed for indicating secondary cell dormancy for each secondary cell of the UE, and a first bit of the set of fields corresponds to a first secondary cell of the UE.

In some embodiments, in the case that a one-shot HARQ-ACK request field is absent from the DCI format or indicates that one-shot HARQ-ACK feedback is not triggered, a HARQ-ACK retransmission indicator is absent from the DCI format or indicates that HARQ-ACK retransmission is not triggered, and all FDRA fields in the DCI format indicates invalid value, the set of fields in the DCI format is repurposed for indicating secondary cell dormancy for each secondary cell of the UE.

In some embodiments, the DCI may include a first indicator indicating whether the set of fields in the DCI format is repurposed for indicating secondary cell dormancy for each secondary cell of the UE, or a second indicator in the DCI format is used for indicating secondary cell dormancy for each secondary cell group of the UE.

In some embodiments, in the case that the first indicator indicates that the set of fields in the DCI format is repurposed for indicating secondary cell dormancy for each secondary cell of the UE, the DCI format does not schedule any data transmission. In some embodiments, in the case that the first indicator indicates that the second indicator in the DCI format is used for indicating secondary cell dormancy for each secondary cell group of the UE, the DCI format schedules one or more data transmissions for the UE.

In some embodiments, the set of fields may include one or more FDRA fields corresponding to one or more cells with smallest serving cell indices among a second set of cells. In some embodiments, the second set of cells is indicated by the DCI format among the first set of cells in response to the DCI format including an indicator indicating scheduled cells, otherwise the second set of cells is the first set of cells.

In some embodiments, the first set of cells may include a primary cell of the UE. In some embodiments, in the case that a one-shot HARQ-ACK request field is absent from the DCI format or indicates that one-shot HARQ-ACK feedback is not triggered, a HARQ-ACK retransmission indicator is absent from the DCI format or indicates that HARQ-ACK retransmission is not triggered, and all FDRA fields in the DCI format except a FDRA field for the primary cell indicates invalid value, the set of fields in the DCI format is repurposed for indicating secondary cell dormancy for each secondary cell of the UE.

In some embodiments, the set of fields does not include a field used for the primary cell.

In some embodiments, whether the primary cell is scheduled by the DCI format or not is based on whether the FDRA field for the primary cell indicates a valid value or invalid value or based on whether a scheduled cell combination indicated by the DCI format includes the primary cell or not.

In some embodiments, in the case that a one-shot HARQ-ACK request field is absent from the DCI format or indicates that one-shot HARQ-ACK feedback is not triggered, a HARQ-ACK retransmission indicator is absent from the DCI format or indicates that HARQ-ACK retransmission is not triggered, and at least one FDRA field in the DCI format indicates an invalid value, the set of fields in the DCI format is repurposed for indicating secondary cell dormancy for each secondary cell of the UE.

In some embodiments, the at least one processor is further configured to cause the BS to determine the number of the at least one FDRA field based on a number of secondary cells configured for the UE.

In some embodiments, the set of fields is specifically used for a cell with a smallest serving cell index among one or more cells within a second set of cells with corresponding FDRA fields in the DCI format indicating invalid value. In some embodiments, the second set of cells is indicated by the DCI format among the first set of cells in response to the DCI format including an indicator indicating scheduled cells, otherwise the second set of cells is the first set of cells.

In some embodiments, the set of fields are concatenated into a bitmap based indicator according to a predefined rule, and each secondary cell of the UE corresponds to a respective bit in the bitmap based indicator.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE.

In some embodiments, a first value of the first bit may indicate the UE to switch to a dormant BWP of the first secondary cell. In some embodiments, a second value of the first bit may indicate the UE to switch to a first active BWP of the first secondary cell in the case that current active BWP of the first secondary cell is the dormant BWP or may indicate the UE to maintain the current active BWP of the first secondary cell in the case that the current active BWP of the first secondary cell is not the dormant BWP.

In some embodiments, the set of fields may include one or more of the following: a cell-specific field with non-configurable field size; a cell-specific field with configurable field size; and a cell-common field.

Some embodiments of the present disclosure provide a processor. The processor may include at least one controller coupled with at least one memory and configured to cause the processor to: receive, from a BS, a signaling configuring a first set of cells for multi-cell scheduling by a DCI format and CRC of the DCI format is scrambled by a C-RNTI or an MCS-C-RNTI of a UE; receive the DCI format from the BS; determine whether a set of fields in the DCI format is repurposed for indicating secondary cell dormancy for each secondary cell of the UE, wherein a first bit of the set of fields corresponds to a first secondary cell of the UE; and switch to a dormant BWP of the first secondary cell of the UE in response to the first bit indicating dormancy for the first secondary cell.

Some embodiments of the present disclosure provide a processor. The processor may include at least one controller coupled with at least one memory and configured to cause the processor to: transmit, to a UE, a signaling configuring a first set of cells for multi-cell scheduling by a DCI format and CRC of the DCI format is scrambled by a C-RNTI or an MCS-C-RNTI of the UE; and transmit the DCI format to the UE, wherein the DCI format may indicate whether a set of fields in the DCI format is repurposed for indicating secondary cell dormancy for each secondary cell of the UE, and a first bit of the set of fields corresponds to a first secondary cell of the UE.

Some embodiments of the present disclosure provide a method for wireless communication. The method may include: receiving, from a BS, a signaling configuring a first set of cells for multi-cell scheduling by a DCI format and CRC of the DCI format is scrambled by a C-RNTI or an MCS-C-RNTI of a UE; receiving the DCI format from the BS; determining whether a set of fields in the DCI format is repurposed for indicating secondary cell dormancy for each secondary cell of the UE, wherein a first bit of the set of fields corresponds to a first secondary cell of the UE; and switching to a dormant BWP of the first secondary cell of the UE in response to the first bit indicating dormancy for the first secondary cell.

Some embodiments of the present disclosure provide a method for wireless communication. The method may include: transmitting, to a UE, a signaling configuring a first set of cells for multi-cell scheduling by a DCI format and CRC of the DCI format is scrambled by a C-RNTI or an MCS-C-RNTI of the UE; and transmitting the DCI format to the UE, wherein the DCI format may indicate whether a set of fields in the DCI format is repurposed for indicating secondary cell dormancy for each secondary cell of the UE, and a first bit of the set of fields corresponds to a first secondary cell of the UE.

Some embodiments of the present disclosure provide an apparatus. According to some embodiments of the present disclosure, the apparatus may include: at least one non-transitory computer-readable medium having stored thereon computer-executable instructions; at least one receiving circuitry; at least one transmitting circuitry; and at least one processor coupled to the at least one non-transitory computer-readable medium, the at least one receiving circuitry and the at least one transmitting circuitry, wherein the at least one non-transitory computer-readable medium and the computer executable instructions may be configured to, with the at least one processor, cause the apparatus to perform a method according to some embodiments of the present disclosure.

### BRIEF DESCRIPTION OF THE DRAWINGS

In order to describe the manner in which the advantages and features of the disclosure can be obtained, a description of the disclosure is rendered by reference to specific embodiments thereof, which are illustrated in the appended drawings. These drawings depict only exemplary embodiments of the disclosure and are not therefore to be considered limiting of its scope.

FIG. 1 illustrates a schematic diagram of a wireless communication system in accordance with some embodiments of the present disclosure;

FIG. 2 illustrates an exemplary bitmap based indicator for indicating the dormancy for a plurality of SCells of a UE in accordance with some embodiments of the present disclosure;

FIGS. 3 and 4 illustrate flowcharts of methods for wireless communication in accordance with some embodiments of the present disclosure;

FIG. 5 illustrates an example of a UE in accordance with some embodiments of the present disclosure;

FIG. 6 illustrates an example of a processor in accordance with some embodiments of the present disclosure; and

FIG. 7 illustrates an example of a network equipment (NE) in accordance with some embodiments of the present disclosure.

### DETAILED DESCRIPTION

The detailed description of the appended drawings is intended as a description of the preferred embodiments of the present disclosure and is not intended to represent the only form in which the present disclosure may be practiced. It should be understood that the same or equivalent functions may be accomplished by different embodiments that are intended to be encompassed within the spirit and scope of the present disclosure.

Reference will now be made in detail to some embodiments of the present disclosure, examples of which are illustrated in the accompanying drawings. To facilitate understanding, embodiments are provided under a specific network architecture(s) and new service scenarios, such as the 3rd generation partnership project (3GPP) 5G NR or 6G, 3GPP LTE, and so on. It is contemplated that along with the developments of network architectures and new service scenarios, all embodiments in the present disclosure are also applicable to similar technical problems; and moreover, the terminologies recited in the present disclosure may change, which should not affect the principles of the present disclosure.

A UE in a wireless communication system can be configured with one or more SCells. However, at least one of the one or more SCells may not always be used for data transmission. It is desired to change a SCell from a non-dormant BWP to a dormant BWP to save power.

To solve the above issue, SCell dormancy indication for multiple SCells of a UE may be supported in a multi-cell scheduling DCI format. Embodiments of the present disclosure provide solutions for supporting SCell dormancy indication in a DCI format.

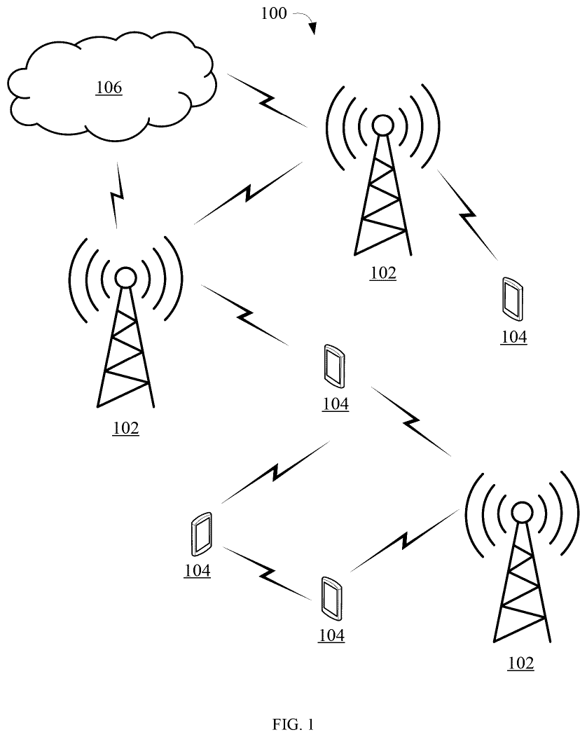

FIG. 1 illustrates a schematic diagram of wireless communication system 100 in accordance with some embodiments of the present disclosure.

The wireless communication system 100 may include one or more NEs 102 (e.g., one or more BSs), one or more UEs 104, and a core network (CN) 106. The wireless communication system 100 may support various radio access technologies. In some implementations, the wireless communication system 100 may be a 4G network, such as an LTE network or an LTE-Advanced (LTE-A) network. In some other implementations, the wireless communication system 100 may be a NR network, such as a 5G network, a 5G-Advanced (5G-A) network, or a 5G ultra-wideband (5G-UWB) network. In other implementations, the wireless communication system 100 may be a combination of a 4G network and a 5G network, or other suitable radio access technology including Institute of Electrical and Electronics Engineers (IEEE) 802.11 (Wi-Fi), IEEE 802.16 (WiMAX), and IEEE 802.20. The wireless communication system 100 may support radio access technologies beyond 5G, for example, 6G. Additionally, the wireless communication system 100 may support technologies, such as time division multiple access (TDMA), frequency division multiple access (FDMA), or code division multiple access (CDMA), etc.

The one or more NEs 102 may be dispersed throughout a geographic region to form the wireless communication system 100. One or more of the NEs 102 described herein may be or include or may be referred to as a network node, a base station, a network element, a network function, a network entity, a radio access network (RAN), a NodeB, an eNodeB (eNB), a next-generation NodeB (gNB), or other suitable terminology. An NE 102 and a UE 104 may communicate via a communication link, which may be a wireless or wired connection. For example, an NE 102 and a UE 104 may perform wireless communication (e.g., receive signaling, transmit signaling) over a Uu interface.

An NE 102 may provide a geographic coverage area for which the NE 102 may support services for one or more UEs 104 within the geographic coverage area. For example, an NE 102 and a UE 104 may support wireless communication of signals related to services (e.g., voice, video, packet data, messaging, broadcast, etc.) according to one or multiple radio access technologies. In some implementations, an NE 102 may be moveable, for example, a satellite associated with a non-terrestrial network (NTN). In some implementations, different geographic coverage areas 112 associated with the same or different radio access technologies may overlap, but the different geographic coverage areas may be associated with a different NE 102.

The one or more UEs 104 may be dispersed throughout a geographic region of the wireless communication system 100. A UE 104 may include or may be referred to as a remote unit, a mobile device, a wireless device, a remote device, a subscriber device, a transmitter device, a receiver device, or some other suitable terminology. In some implementations, the UE 104 may be referred to as a unit, a station, a terminal, or a client, among other examples. Additionally, or alternatively, the UE 104 may be referred to as an Internet-of-Things (IOT) device, an Internet-of-Everything (IoE) device, or machine-type communication (MTC) device, among other examples.

A UE 104 may be able to support wireless communication directly with other UEs 104 over a communication link. For example, a UE 104 may support wireless communication directly with another UE 104 over a device-to-device (D2D) communication link. In some implementations, such as vehicle-to-vehicle (V2V) deployments, vehicle-to-everything (V2X) deployments, or cellular-V2X deployments, the communication link 114 may be referred to as a sidelink. For example, a UE 104 may support wireless communication directly with another UE 104 over a PC5 interface.

An NE 102 may support communication with the CN 106, or with another NE 102, or both. For example, an NE 102 may interface with another NE 102 or the CN 106 through one or more backhaul links (e.g., S1, N2, N3 or another network interface). In some implementations, the NE 102 may communicate with each other directly. In some other implementations, the NE 102 may communicate with each other or indirectly (e.g., via the CN 106. In some implementations, one or more NEs 102 may include subcomponents, such as an access network entity, which may be an example of an access node controller (ANC). An ANC may communicate with the one or more UEs 104 through one or more other access network transmission entities, which may be referred to as radio heads, smart radio heads, or transmission-reception points (TRPs).

The CN 106 may support user authentication, access authorization, tracking, connectivity, and other access, routing, or mobility functions. The CN 106 may be an evolved packet core (EPC), or a 5G core (5GC), which may include a control plane entity that manages access and mobility (e.g., a mobility management entity (MME), an access and mobility management functions (AMF)) and a user plane entity that routes packets or interconnects to external networks (e.g., a serving gateway (S-GW), a Packet Data Network (PDN) gateway (P-GW), or a user plane function (UPF)). In some implementations, the control plane entity may manage non-access stratum (NAS) functions, such as mobility, authentication, and bearer management (e.g., data bearers, signal bearers, etc.) for the one or more UEs 104 served by the one or more NEs 102 associated with the CN 106.

The CN 106 may communicate with a packet data network over one or more backhaul links (e.g., via an S1, N2, N3, or another network interface). The packet data network may include an application server. In some implementations, one or more UEs 104 may communicate with the application server. A UE 104 may establish a session (e.g., a protocol data unit (PDU) session, or the like) with the CN 106 via an NE 102. The CN 106 may route traffic (e.g., control information, data, and the like) between the UE 104 and the application server using the established session (e.g., the established PDU session). The PDU session may be an example of a logical connection between the UE 104 and the CN 106 (e.g., one or more network functions of the CN 106).

In the wireless communication system 100, the NEs 102 and the UEs 104 may use resources of the wireless communication system 100 (e.g., time resources (e.g., symbols, slots, subframes, frames, or the like) or frequency resources (e.g., subcarriers, carriers)) to perform various operations (e.g., wireless communication). In some implementations, the NEs 102 and the UEs 104 may support different resource structures. For example, the NEs 102 and the UEs 104 may support different frame structures. In some implementations, such as in 4G, the NEs 102 and the UEs 104 may support a single frame structure. In some other implementations, such as in 5G and among other suitable radio access technologies, the NEs 102 and the UEs 104 may support various frame structures (i.e., multiple frame structures). The NEs 102 and the UEs 104 may support various frame structures based on one or more numerologies.

One or more numerologies may be supported in the wireless communication system 100, and a numerology may include a subcarrier spacing and a cyclic prefix. A first numerology (e.g., μ=0) may be associated with a first subcarrier spacing (e.g., 15 kHz) and a normal cyclic prefix. In some implementations, the first numerology (e.g., μ=0) associated with the first subcarrier spacing (e.g., 15 kHz) may utilize one slot per subframe. A second numerology (e.g., μ=1) may be associated with a second subcarrier spacing (e.g., 30 kHz) and a normal cyclic prefix. A third numerology (e.g., μ=2) may be associated with a third subcarrier spacing (e.g., 60 kHz) and a normal cyclic prefix or an extended cyclic prefix. A fourth numerology (e.g., μ=3) may be associated with a fourth subcarrier spacing (e.g., 120 kHz) and a normal cyclic prefix. A fifth numerology (e.g., μ=4) may be associated with a fifth subcarrier spacing (e.g., 240 kHz) and a normal cyclic prefix. A sixth numerology (e.g., μ=5) may be associated with a sixth subcarrier spacing (e.g., 480 kHz) and a normal cyclic prefix. A seventh numerology (e.g., μ=6) may be associated with a seventh subcarrier spacing (e.g., 960 kHz) and a normal cyclic prefix.

A time interval of a resource (e.g., a communication resource) may be organized according to frames (also referred to as radio frames). Each frame may have a duration, for example, a 10 millisecond (ms) duration. In some implementations, each frame may include multiple subframes. For example, each frame may include 10 subframes, and each subframe may have a duration, for example, a 1 ms duration. In some implementations, each frame may have the same duration. In some implementations, each subframe of a frame may have the same duration.

Additionally or alternatively, a time interval of a resource (e.g., a communication resource) may be organized according to slots. For example, a subframe may include a number (e.g., quantity) of slots. The number of slots in each subframe may also depend on the one or more numerologies supported in the wireless communication system 100. For instance, the first, second, third, fourth, and fifth numerologies (i.e., μ=0, μ=1, μ=2, μ=3, μ=4) associated with respective subcarrier spacings of 15 kHz, 30 kHz, 60 kHz, 120 kHz, and 240 kHz may utilize a single slot per subframe, two slots per subframe, four slots per subframe, eight slots per subframe, and 16 slots per subframe, respectively. Each slot may include a number (e.g., quantity) of symbols (e.g., orthogonal frequency-division multiplexing (OFDM) symbols). In some implementations, the number (e.g., quantity) of slots for a subframe may depend on a numerology. For a normal cyclic prefix, a slot may include 14 symbols. For an extended cyclic prefix (e.g., applicable for 60 kHz subcarrier spacing), a slot may include 12 symbols. The relationship between the number of symbols per slot, the number of slots per subframe, and the number of slots per frame for a normal cyclic prefix and an extended cyclic prefix may depend on a numerology. It should be understood that reference to a first numerology (e.g., μ=0) associated with a first subcarrier spacing (e.g., 15 kHz) may be used interchangeably between subframes and slots.

In the wireless communication system 100, an electromagnetic (EM) spectrum may be split, based on frequency or wavelength, into various classes, frequency bands, frequency channels, etc. By way of example, the wireless communication system 100 may support one or multiple operating frequency bands, such as frequency range designations FR1 (410 MHz-7.125 GHZ), FR2 (24.25 GHz-52.6 GHZ), FR3 (7.125 GHz-24.25 GHZ), FR4 (52.6 GHz-114.25 GHZ), FR4a or FR4-1 (52.6 GHz-71 GHz), and FR5 (114.25 GHz-300 GHz). In some implementations, the NEs 102 and the UEs 104 may perform wireless communication over one or more of the operating frequency bands. In some implementations, FR1 may be used by the NEs 102 and the UEs 104, among other equipment or devices for cellular communication traffic (e.g., control information, data). In some implementations, FR2 may be used by the NEs 102 and the UEs 104, among other equipment or devices for short-range, high data rate capabilities.

FR1 may be associated with one or multiple numerologies (e.g., at least three numerologies). For example, FRI may be associated with a first numerology (e.g., μ=0), which includes 15 kHz subcarrier spacing; a second numerology (e.g., μ=1), which includes 30 kHz subcarrier spacing; and a third numerology (e.g., μ=2), which includes 60 kHz subcarrier spacing. FR2 may be associated with one or multiple numerologies (e.g., at least 2 numerologies). For example, FR2 may be associated with a third numerology (e.g., μ=2), which includes 60 kHz subcarrier spacing; and a fourth numerology (e.g., μ=3), which includes 120 kHz subcarrier spacing.

A UE 104 may include computing devices, such as desktop computers, laptop computers, personal digital assistants (PDAs), tablet computers, smart televisions (e.g., televisions connected to the Internet), set-top boxes, game consoles, security systems (including security cameras), vehicle on-board computers, network devices (e.g., routers, switches, and modems), or the like. According to some embodiments of the present disclosure, a UE 104 may include a portable wireless communication device, a smart phone, a cellular telephone, a flip phone, a device having a subscriber identity module, a personal computer, a selective call receiver, or any other device that is capable of sending and receiving communication signals on a wireless network. In some embodiments of the present disclosure, a UE 104 includes wearable devices, such as smart watches, fitness bands, optical head-mounted displays, or the like. Moreover, a UE 104 may be referred to as a subscriber unit, a mobile, a mobile station, a user, a terminal, a mobile terminal, a wireless terminal, a fixed terminal, a subscriber station, a user terminal, or a device, or described using other terminology used in the art. A UE 104 may communicate with an NE 102 (e.g., a BS) via uplink (UL) communication signals. An NE 102 may communicate with a UE 104 via downlink (DL) communication signals.

In some embodiments of the present disclosure, an NE 102 and a UE 104 may communicate over licensed spectrums, whereas in some other embodiments, an NE 102 and a UE 104 may communicate over unlicensed spectrums. The present disclosure is not intended to be limited to the implementation of any particular wireless communication system architecture or protocol.

In some embodiments of the present disclosure, the wireless communication system 100 may be designed to support CA. To reduce signaling overhead in the case of CA, multi-cell data transmission (e.g., physical uplink shared channel (PUSCH) or physical downlink shared channel (PDSCH)) scheduling with a single scheduling DCI format is supported and is referred to as multi-cell scheduling in the context of the present disclosure. For example, a dedicate UL DCI format (e.g., DCI format 0_3) may be introduced for scheduling up to 4 PUSCHs on 4 cells with each PUSCH per cell. For example, a dedicate DL DCI format (e.g., DCI format 1_3) may be introduced for scheduling up to 4 PDSCHs on 4 cells with each PDSCH per cell.

For example, in some embodiments of the present disclosure, a BS may configure a set of cells which can be used for multi-cell scheduling for a UE. For example, the BS may transmit a DCI format to the UE, and the DCI format may schedule one or more downlink data transmissions (e.g., PDSCHs) or uplink data transmissions (e.g., PUSCHs) on one or more cells in the configured cell set. The one or more scheduled cells is indicated by the DCI format among the configured cell set, that is, indicated by an indicator in the DCI format if the indicator is included in the DCI format; otherwise, if the DCI format does not include such an indicator, the one or more scheduled cells are all cells in the configured cell set. For clarity, such an indicator is hereinafter referred to as a scheduled cell indicator.

A UE in a wireless communication system can be configured with one or more SCells. However, at least one of the one or more SCells may not always be used for data transmission. It is desired to change a SCell from a non-dormant BWP to a dormant BWP to save power. A dormant BWP may be configured by the network for the SCell via dedicated RRC signaling as one of downlink BWPs of the SCell. In the dormant BWP, the UE may stop monitoring PDCCH on or for the SCell, but may continue performing channel state information (CSI) measurements, automatic gain control (AGC) and beam management, if configured. Solutions for SCell dormancy indication for multiple SCells of a UE is thus required.

In some embodiments of the present disclosure, a multi-cell scheduling DCI format can indicate secondary cell dormancy for multiple secondary cells of a UE. For example, a set of fields in the DCI format may be repurposed for indicating secondary cell dormancy for each secondary cell of the UE. More details on the embodiments of the present disclosure will be illustrated in the following text in combination with the appended drawings.

In some embodiments of the present disclosure, a BS may configure a set of cells (denoted as cell set #1 for clarity) for multi-cell scheduling by a DCI format. In some embodiments, the CRC of the DCI format may be scrambled by a C-RNTI or an MCS-C-RNTI of the UE. As will be descried in details in the following text, the DCI format may implicitly or explicitly indicate whether a set of fields in the DCI format is repurposed for indicating secondary cell dormancy for each secondary cell of the UE.

In some embodiments of the present disclosure, when a multi-cell DCI format is used to indicate SCell dormancy for each configured SCell of a UE, this DCI format does not schedule any data transmissions. An invalid value is indicated in each FDRA field in the DCI format. The DCI format is transmitted on a primary cell (PCell) of the UE.

In some embodiments, for a FDRA field in a DCI format, when all bits of the FDRA field is set to ‘0’ for resource allocation type 0, or set to ‘1’ for resource allocation type 1, or set to ‘0’ or ‘1’ for dynamic switch resource allocation type, or set to ‘0’ for resource allocation type 2 with 30 kHz subcarrier spacing (SCS) or ‘1’ for resource allocation type 2 with 15 kHz SCS, this FDRA field indicates an invalid value; otherwise, this FDRA field indicates a valid value.

From the perspective of a UE, in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and all FDRA fields in the DCI format indicating invalid value, the UE can determine that a set of fields (denoted as field set #A) in the DCI format is repurposed for indicating secondary cell dormancy for each secondary cell of the UE; otherwise, the DCI format does not indicate per SCell dormancy for any secondary cell of the UE. From the perspective of a BS, depending on whether the DCI format is used to indicate per SCell dormancy for the secondary cell(s) of the UE, it can set the fields in the DCI format accordingly.

In some embodiments, fields in field set #A may be concatenated into an indicator (denoted as bitmap based indicator) according to a predefined rule, and each secondary cell of the UE corresponds to a respective bit in the bitmap based indicator. Details about the fields included in field set #A and the predefined rule for ordering these fields will be described later.

In some embodiments, the mapping relationship between the bits in the bitmap based indicator and the configured secondary cells of the UE may be predefined. In some embodiments, the configured SCells can be respectively mapped to the most significant bit (MSB) to the least significant bit (LSB) of the bitmap based indicator according to an ascending order of SCell indexes. For example, the MSB of the bitmap based indicator can indicate dormancy for the SCell with the lowest SCell index, the bit following the MSB can indicate dormancy for the SCell with the second lowest SCell index, and so on. In some embodiments, the configured SCells can be respectively mapped to the MSB to the LSB of the bitmap based indicator according to a descending order of SCell indexes. In some embodiments, the configured SCells can be respectively mapped to the LSB to the MSB of the bitmap based indicator according to an ascending order of SCell indexes. In some embodiments, the configured SCells can be respectively mapped to the LSB to the MSB of the bitmap based indicator according to a descending order of SCell indexes.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE. For example, assuming that the bitmap based indicator includes 16 bits and the UE is configured with 8 SCells, then 8 bits is sufficient for SCell dormancy indication. In some embodiments, the 8 MSBs of the bitmap based indicator can be used to indicate the SCell dormancy for the UE and the remaining bits in the bitmap based indicator can be ignored. In some embodiments, the 8 LSBs of the bitmap based indicator can be used to indicate the SCell dormancy for the UE and the remaining bits in the bitmap based indicator can be ignored.

A specific bit (denoted as bit #A) in the bitmap based indicator can be used to indicate dormancy for a corresponding secondary cell (denoted as cell #A) of the UE. In some embodiments, a value (e.g., ‘0’ or ‘1’) of bit #A may indicate the UE to switch to a dormant BWP of cell #A. Another value (e.g., ‘1’ or ‘0’) of bit #A may indicate the UE to switch to a first active BWP of cell #A in the case that current active BWP of cell #A is the dormant BWP or may indicate the UE to maintain the current active BWP of cell #A in the case that the current active BWP of cell #A is not the dormant BWP.

The DCI format may indicate a set of cells (denoted as cell set #2) among cell set #1 by, for example, a scheduled cell indicator in the DCI format if exists, otherwise cell set #2 is cell set #1. In the case that the DCI format is used to indicate SCell dormancy, cells in cell set #2 are not actually scheduled by the DCI format. Fields specific for cells in cell set #2 in the DCI format can be repurposed for indicating secondary cell dormancy for each secondary cell of the UE. Cell-common fields such as a demodulation reference signal (DMRS) sequence initialization field and a BWP indicator field can also be repurposed for secondary cell dormancy indication.

In some embodiments, field set #A may include one or more of fields in the DCI format: a cell-specific field with non-configurable field size (e.g., a modulation and coding scheme (MCS) field or a new data indicator (NDI) field); a cell-specific field with configurable field size (e.g., a redundancy version (RV) field, a HARQ process number field or an antenna port field if configured as the cell-specific type); and a cell-common field (e.g., a DMRS sequence initialization field or a BWP indicator field).

Field set #A may not include an FDRA field as each FDRA field in the DCI format indicates an invalid value. The number of FDRA fields (denoted as N) in the DCI format may be equal to the number of cells in cell set #2. In the case that a list of scheduled cell combinations is configured for the UE (e.g., via RRC signaling), the scheduled cell indicator in the DCI format may indicate a cell combination from the list of scheduled cell combinations. The indicated cell combination is cell set #2 and Nis the number of cells in the indicated cell combination. As a special case, the list of scheduled cell combinations may include only one cell combination, then N is the number of cells in the single cell combination. In the case that the list of scheduled cell combinations is not configured for the UE, the DCI format does not include the scheduled cell indicator, then cell set #2 is cell set #1, and N is the number of cells in cell set #1. The N FDRA fields in the DCI format can be placed according to predefined order (e.g., an ascending or descending order) of the corresponding serving cell index of the cells in cell set #2. For example, when an ascending order of serving cell indexes is employed, the first FDRA field may correspond to the frequency domain resource assignment for the cell with the smallest serving cell index in cell set #2.

In some examples, field set #A may include a field(s) specifically used for a cell (e.g., one cell) with the smallest serving cell index among one or more cells within cell set #2 with corresponding FDRA fields in the DCI format indicating invalid value. In some examples, field set #A may include a field(s) specifically used for one or more cells with the smallest serving cell indexes among cell set #2 with corresponding FDRA fields in the DCI format indicating valid value.

Fields in field set #A can be ordered according to a predefined rule. For example, cell-specific fields in field set #A may be ordered in a cell index-first and field type-second order. For example, cell-specific fields in field set #A may be ordered in a field type-first and cell index-second order. The order of cell indexes here may refer to an ascending or descending order of cell indexes of the cells in cell set #2. Any other ordering method that can be conceived of by persons skilled in the art can apply.

The following shows some exemplary examples of field set #A and should not be construed as limiting the embodiments of the present disclosure. For simplicity, in the following examples, an ascending order of cell indexes is employed and cells in cell set #2 are denoted as cell #1 to cell #N ordered according to the ascending order of cell indexes.

In some examples, field set #A may only include cell-specific fields with non-configurable field size, which may be ordered according to a cell index-first and field type-second order. For example, field set #A may include an MCS field and an NDI field. For example, field set #A can be ordered as: {MCS of TB1 of cell #1, NDI of TB1 of cell #1, MCS of TB1 of cell #2, NDI of TB1 of Cell #2, . . . , MCS of TB1 of cell #N, NDI of TB1 of cell #N} (hereinafter, denoted as example #A1).

In some examples, field set #A may only include cell-specific fields with non-configurable field size, which may be ordered according to a field type-first and cell index-second order. For example, field set #A may include an MCS field and an NDI field. For example, field set #A can be ordered as: {MCS of TB1 of cell #1, MCS of TB1 of cell #2, . . . , MCS of TB1 of cell #N, NDI of TB1 of cell #1, NDI of TB1 of Cell #2, . . . , NDI of TB1 of cell #N} (hereinafter, denoted as example #A2).

In some examples, field set #A may include cell-specific fields with non-configurable and/or configurable field size, which may be ordered according to a cell index-first and field type-second order. For example, field set #A may include an MCS field, an NDI field, an RV field, a HARQ process number field, and an antenna port field (if configured as the cell-specific type). For example, field set #A can be ordered as: {MCS of TB1 of cell #1, NDI of TB1 of cell #1, RV of TB1 of cell #1, HARQ process number of cell #1, antenna port of cell #1 (if configured as the cell-specific type), MCS of TB1 of cell #2, NDI of TB1 of cell #2, RV of TB1 of cell #2, HARQ process number of cell #2, antenna port of cell #2 (if configured as the cell-specific type), . . . , MCS of TB1 of cell #N, NDI of TB1 of cell #N, RV of TB1 of cell #N, HARQ process number of cell #N, antenna port of cell #N (if configured as the cell-specific type) } (hereinafter, denoted as example #A3).

In some examples, field set #A may include cell-specific fields with non-configurable and/or configurable field size, which may be ordered according to a field type-first and cell index-second order. For example, field set #A may include an MCS field, an NDI field, an RV field, a HARQ process number field, and an antenna port field (if configured as the cell-specific type). For example, field set #A can be ordered as: {MCS of TB1 of cell #1, MCS of TB1 of cell #2, . . . , MCS of TB1 of cell #N, NDI of TB1 of cell #1, NDI of TB1 of cell #2, , NDI of TB1 of cell #N, RV of TB1 of cell #1, RV of TB1 of cell #2, . . . , RV of TB1 of cell #N, HARQ process number of cell #1, HARQ process number of cell #2, . . . , HARQ process number of cell #N, antenna port of cell #1 (if configured as the cell-specific type), antenna port of cell #2 (if configured as the cell-specific type), . . . , antenna port of cell #N (if configured as the cell-specific type)} (hereinafter, denoted as example #A4).

In the above examples, field set #A only includes cell-specific fields for TB1. It should be noted that field set #A may also include cell-specific fields for TB2 (if configured) in some other examples. For example, field set #A may include MCS of TB2, NDI of TB2, RV of TB2, or any combination thereof.

The UE may be configured with up to a maximum number of SCells. For clarity, it is assumed that the maximum number is equal to 15. It should be noted that the maximum number can be any other positive integer.

In some examples, in the case that the field combination of field set #A can provide more than 15 bits for SCell dormancy indication, some fields can be in field set #A can be excluded or reserved.

For example, in example #A3, the total bits of {MCS of TB1 of cell #1 (e.g., 5 bits), NDI of TB1 of cell #1 (e.g., 1 bit), RV of TB1 of cell #1 (e.g., 2 bits), HARQ process number of cell #1 (e.g., 4 bits), antenna port of cell #1 (if configured as the cell-specific type) (e.g., 4 bits) } may be equal to 16 bits. Therefore, field set #A may not need to include {MCS of TB1 of cell #2, NDI of TB1 of cell #2, RV of TB1 of cell #2, HARQ process number of cell #2, antenna port of cell #2 (if configured as the cell-specific type), . . . , MCS of TB1 of cell #N, NDI of TB1 of cell #N, RV of TB1 of cell #N, HARQ process number of cell #N, antenna port of cell #N (if configured as the cell-specific type)}. That is, field set #A may include {MCS of TB1 of cell #1, NDI of TB1 of cell #1, RV of TB1 of cell #1, HARQ process number of cell #1, antenna port of cell #1 (if configured as the cell-specific type)} (hereinafter, denoted as example #A3′).

In some examples, in the case that the field combination of field set #A can provide more bits than the number of SCells configured for the UE, some fields can be in field set #A can be excluded or reserved.

For example, assuming that N=2 and the number of configured SCells=8, the total bits of field set #A in example #A1 may be equal to 12 bits. Therefore, field set #A may not need to include {NDI of TB1 of Cell #2 (e.g., 1 bit)}. Field set #A may include {MCS of TB1 of cell #1 (e.g., 5 bits), NDI of TB1 of cell #1 (e.g., 1 bit), MCS of TB1 of cell #2 (e.g., 5 bits)} (hereinafter, denoted as example #A1′), and thus provide 11 bits which is larger than the number of configured SCells (i.e., 8).

Since the number of SCells configured for a UE is variable, in case that the field combination of field set #A provides more bits than the number of configured SCells, some bits of the field combination are reserved as long as the remaining bits can provide sufficient bits for SCell dormancy indication. For example, as mentioned above, one or more bits in the bitmap based indicator formed by field set #A may be reserved, depending on a number of SCells configured for the UE. For example, assuming that N=2 and the number of configured SCells=8, according to example #A 1′, 3 (i.e., 11-8) bits in the bitmap based indicator may be reserved.

Generally, it is expected that the number of bits of the field combination of field set #A is not less than 15 or the number of SCells configured for the UE. However, in the case that the number of bits of the field combination of field set #A (e.g., the size of the bitmap based indicator) is less than the number of SCells configured for the UE, the bitmap based indicator may not be able to indicate per SCell dormancy for one or more SCells of the UE (e.g., SCells with highest SCell indexes), or alternatively, one bit in the field combination of field set #A may be used to indicate dormancy for a corresponding secondary cell group of the UE.

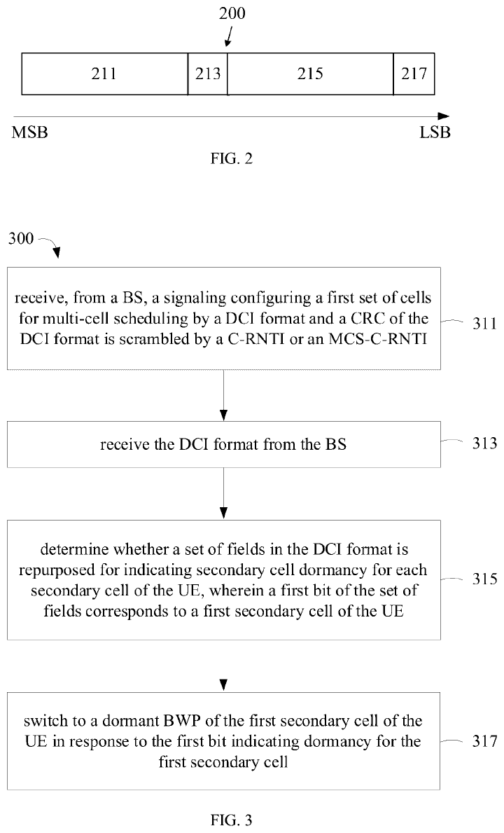

FIG. 2 illustrates exemplary bitmap based indicator 200 in accordance with some embodiments of the present disclosure. Assuming that N=2, according to example #A1, field set #A may include {MCS of TB1 of cell #1 (denoted as 211 in FIG. 2), NDI of TB1 of cell #1 (denoted as 213 in FIG. 2), MCS of TB1 of cell #2 (denoted as 215 in FIG. 2), NDI of TB1 of Cell #2 (denoted as 217 in FIG. 2)}. Assuming that the number of configured SCells=8, the 8 MSBs of bitmap based indicator 200 may be used to indicate the dormancy for each of the 8 configured SCells and the remaining bits of bitmap based indicator 200 can be reserved (e.g., ignored by the UE). The 8 MSBs of bitmap based indicator 200 may correspond to the SCells from the lowest to the highest SCell index.

In some embodiments of the present disclosure, when a multi-cell DCI format is used to indicate SCell dormancy for each configured SCell of a UE, this DCI format may include an indicator (denoted as indicator #B) indicating whether a set of fields (denoted as field set #B) in the DCI format is repurposed for indicating secondary cell dormancy for each secondary cell of the UE, or another indicator in the DCI format is used for indicating secondary cell dormancy for each secondary cell group of the UE. The DCI format is transmitted on a PCell of the UE. In some embodiments, up to 5 SCell groups can be configured by RRC signaling so that up to 5 bits are needed for the another indicator with each bit corresponding to one SCell group. Other maximum number of SCell groups may be supported in some other embodiments.

In some embodiments, in the case that indicator #B indicates field set #B in the DCI format being repurposed for indicating secondary cell dormancy for each secondary cell of the UE, the DCI format does not schedule any data transmission and one or more FDRA fields in the DCI format may be repurposed for SCell dormancy indication. In the case that indicator #B indicates the another indicator in the DCI format being used for indicating secondary cell dormancy for each secondary cell group of the UE, the DCI format can schedule one or more data transmissions. In some examples, indicator #B may include at least one bit. For example, bit ‘1’ may indicate field repurposing for per secondary cell dormancy indication and bit ‘0’ may indicate another indicator in the DCI format being used for per secondary cell group dormancy indication; or vice versa. In some embodiments, each bit in the another indicator may corresponding to one secondary cell group.

From the perspective of a UE, the UE may determine whether a set of fields (e.g., field set #B) in a DCI format is repurposed for indicating secondary cell dormancy for each secondary cell of the UE based on indicator #B in the DCI format. If indicator #B indicates field repurposing for secondary cell dormancy indication, the UE can determine that no data transmission is scheduled and one or more FDRA fields in the DCI format may be repurposed for SCell dormancy indication. That is, field set #B may include one or more FDRA fields. The details of field set #B will be described later. If indicator #B indicates that another indicator in the DCI format is used for secondary cell group dormancy indication, the UE may refer to the another indicator to determine the dormancy of each secondary cell group. From the perspective of a BS, it can set the fields in the DCI format accordingly.

In some embodiments, fields in field set #B may be concatenated into an indicator (e.g., bitmap based indicator) according to a predefined rule, and each secondary cell of the UE corresponds to a respective bit in the bitmap based indicator. Details about the fields included in field set #B and the predefined rule for ordering these fields will be described later.

In some embodiments, the mapping relationship between the bits in the bitmap based indicator and the configured secondary cells of the UE may be predefined. In some embodiments, the configured SCells can be respectively mapped to the MSB to the LSB of the bitmap based indicator according to an ascending order of SCell indexes. For example, the MSB of the bitmap based indicator can indicate dormancy for the SCell with the lowest SCell index, the bit following the MSB can indicate dormancy for the SCell with the second lowest SCell index, and so on. In some embodiments, the configured SCells can be respectively mapped to the MSB to the LSB of the bitmap based indicator according to a descending order of SCell indexes. In some embodiments, the configured SCells can be respectively mapped to the LSB to the MSB of the bitmap based indicator according to an ascending order of SCell indexes. In some embodiments, the configured SCells can be respectively mapped to the LSB to the MSB of the bitmap based indicator according to a descending order of SCell indexes.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE. For example, assuming that the bitmap based indicator includes 16 bits and the UE is configured with 8 SCells, then 8 bits is sufficient for SCell dormancy indication. In some embodiments, the 8 MSBs of the bitmap based indicator can be used to indicate the SCell dormancy for the UE and the remaining bits in the bitmap based indicator can be ignored. In some embodiments, the 8 LSBs of the bitmap based indicator can be used to indicate the SCell dormancy for the UE and the remaining bits in the bitmap based indicator can be ignored.

A specific bit (denoted as bit #B) in the bitmap based indicator can be used to indicate dormancy for a corresponding secondary cell (denoted as cell #B) of the UE. In some embodiments, a value (e.g., ‘0’ or ‘1’) of bit #B may indicate the UE to switch to a dormant BWP of cell #B. Another value (e.g., ‘1’ or ‘0’) of bit #B may indicate the UE to switch to a first active BWP of cell #B in the case that current active BWP of cell #B is the dormant BWP or may indicate the UE to maintain the current active BWP of cell #B in the case that the current active BWP of cell #B is not the dormant BWP.

The DCI format may indicate a set of cells (e.g., cell set #2) among cell set #1 by, for example, a scheduled cell indicator in the DCI format if exists, otherwise cell set #2 is cell set #1. In the case that indicator #B indicates field repurposing for secondary cell dormancy indication, cells in cell set #2 are not actually scheduled by the DCI format. Fields specific for cells (e.g., FDRA field) in cell set #2 in the DCI format can be repurposed for indicating secondary cell dormancy for each secondary cell of the UE. Cell-common fields can also be repurposed for secondary cell dormancy indication.

In some embodiments, field set #B may include one or more of fields in the DCI format: a cell-specific field with non-configurable field size; a cell-specific field with configurable field size; and a cell-common field.

As described above, the number of FDRA fields (e.g., N) in the DCI format may be equal to the number of cells in cell set #2. In the case that a list of scheduled cell combinations is configured for the UE (e.g., via RRC signaling), the scheduled cell indicator in the DCI format may indicate a cell combination from the list of scheduled cell combinations. The indicated cell combination is cell set #2 and N is the number of cells in the indicated cell combination. As a special case, the list of scheduled cell combinations may include only one cell combination, then N is the number of cells in the single cell combination. In the case that the list of scheduled cell combinations is not configured for the UE, the DCI format does not include the scheduled cell indicator, then cell set #2 is cell set #1, and N is the number of cells in cell set #1. The N FDRA fields in the DCI format can be placed according to predefined order (e.g., an ascending or descending order) of the corresponding serving cell index of the cells in cell set #2. For example, when an ascending order of serving cell indexes is employed, the first FDRA field may correspond to the frequency domain resource assignment for the cell with the smallest serving cell index in cell set #2.

With indicator #B, the FDRA fields in the DCI format do not have to be set as an invalid value. In some embodiments, field set #B may include one or more FDRA fields corresponding to one or more cells with the smallest serving cell indexes among cell set #2.

In some examples, field set #B may include a field(s) specifically used for a cell (e.g., one cell) with the smallest serving cell index among one or more cells within cell set #2 with corresponding FDRA fields in the DCI format indicating invalid value. In some examples, field set #B may include a field(s) specifically used for one or more cells with the smallest serving cell indexes among cell set #2 with corresponding FDRA fields in the DCI format indicating valid value.

Fields in field set #B can be ordered according to a predefined rule. For example, cell-specific fields in field set #B may be ordered in a cell index-first and field type-second order. For example, cell-specific fields in field set #B may be ordered in a field type-first and cell index-second order. The order of cell indexes here may refer to an ascending or descending order of cell indexes of the cells in cell set #2. Any other ordering method that can be conceived of by persons skilled in the art can apply.

The following shows some exemplary examples of field set #B and should not be construed as limiting the embodiments of the present disclosure. For simplicity, in the following examples, an ascending order of cell indexes is employed and cells in cell set #2 are denoted as cell #1 to cell #N ordered according to the ascending order of cell indexes.

In some examples, field set #B may only include FDRA fields, which may be ordered according to the cell indexes. For example, field set #B can be ordered as: {FDRA of cell #1, FDRA of cell #2, . . . , FDRA of cell #N} (hereinafter, denoted as example #B1).

In some examples, field set #B may only include cell-specific fields with non-configurable field size, which may be ordered according to a cell index-first and field type-second order. For example, field set #B may include an FDRA field, an MCS field and an NDI field. For example, field set #B can be ordered as: {FDRA of cell #1, MCS of TB1 of cell #1, NDI of TB1 of cell #1, FDRA of cell #2, MCS of TB1 of cell #2, NDI of TB1 of Cell #2, . . . , FDRA of cell #N, MCS of TB1 of cell #N, NDI of TB1 of cell #N} (hereinafter, denoted as example #B2).

In some examples, field set #B may only include cell-specific fields with non-configurable field size, which may be ordered according to a field type-first and cell index-second order. For example, field set #B may include an FDRA field, an MCS field and an NDI field. For example, field set #B can be ordered as: {FDRA of cell #1, FDRA of cell #2, . . . , FDRA of cell #N, MCS of TB1 of cell #1, MCS of TB1 of cell #2, . . . , MCS of TB1 of cell #N, NDI of TB1 of cell #1, NDI of TB1 of Cell #2, NDI of TB1 of cell #N} (hereinafter, denoted as example #B3).

In some examples, field set #B may include cell-specific fields with non-configurable and/or configurable field size, which may be ordered according to a cell index-first and field type-second order. For example, field set #B may include an FDRA field, an MCS field, an NDI field, an RV field, a HARQ process number field, and an antenna port field (if configured as the cell-specific type). For example, field set #B can be ordered as: {FDRA of cell #1, MCS of TB1 of cell #1, NDI of TB1 of cell #1, RV of TB1 of cell #1, HARQ process number of cell #1, antenna port of cell #1 (if configured as the cell-specific type), FDRA of cell #2, MCS of TB1 of cell #2, NDI of TB1 of cell #2, RV of TB1 of cell #2, HARQ process number of cell #2, antenna port of cell #2 (if configured as the cell-specific type), . . . , FDRA of cell #N, MCS of TB1 of cell #N, NDI of TB1 of cell #N, RV of TB1 of cell #N, HARQ process number of cell #N, antenna port of cell #N (if configured as the cell-specific type)} (hereinafter, denoted as example #B4).

In some examples, field set #B may include cell-specific fields with non-configurable and/or configurable field size, which may be ordered according to a field type-first and cell index-second order. For example, field set #B may include an FDRA field, an MCS field, an NDI field, an RV field, a HARQ process number field, and an antenna port field (if configured as the cell-specific type). For example, field set #B can be ordered as: {FDRA of cell #1, FDRA of cell #2, . . . , FDRA of cell #N, MCS of TB1 of cell #1, MCS of TB1 of cell #2, . . . , MCS of TB1 of cell #N, NDI of TB1 of cell #1, NDI of TB1 of cell #2, . . . , NDI of TB1 of cell #N, RV of TB1 of cell #1, RV of TB1 of cell #2, . . . , RV of TB1 of cell #N, HARQ process number of cell #1, HARQ process number of cell #2, . . . , HARQ process number of cell #N, antenna port of cell #1 (if configured as the cell-specific type), antenna port of cell #2 (if configured as the cell-specific type), . . . , antenna port of cell #N (if configured as the cell-specific type)} (hereinafter, denoted as example #B5).

In the above examples, field set #B only includes cell-specific fields for TB1. It should be noted that field set #B may also include cell-specific fields for TB2 (if configured) in some other examples. For example, field set #B may include MCS of TB2, NDI of TB2, RV of TB2, or any combination thereof.

The UE may be configured with up to a maximum number of SCells. For clarity, it is assumed that the maximum number is equal to 15. It should be noted that the maximum number can be any other positive integer.

In some examples, in the case that the field combination of field set #B can provide more than 15 bits for SCell dormancy indication, some fields can be in field set #B can be excluded or reserved.

For example, it is assumed that cell #1 has a bandwidth requiring 10 bits for FDRA indication. In example #B2, the total bits of {FDRA of cell #1, MCS of TB1 of cell #1 (e.g., 5 bits)} is equal to 15 bits. Therefore, field set #B may not need to include {NDI of TB1 of cell #1, FDRA of cell #2, MCS of TB1 of cell #2, NDI of TB1 of Cell #2, . . . , FDRA of cell #N, MCS of TB1 of cell #N, NDI of TB1 of cell #N}. That is, field set #B may include {FDRA of cell #1, MCS of TB1 of cell #1} (hereinafter, denoted as example #B2′).

In some examples, in the case that the field combination of field set #B can provide more bits than the number of SCells configured for the UE, some fields can be in field set #B can be excluded or reserved.

For example, assuming that N=2, the number of configured SCells=8 and cell #1 has a bandwidth requiring 10 bits for FDRA indication, FDRA of cell #1 can provide 10 bits which is larger than the number of configured SCells. Example #B 1 can be modified as {FDRA of cell #1 } (hereinafter, denoted as example #B1′). That is, Field set #B may only include {FDRA of cell #1}.

Since the number of SCells configured for a UE is variable, in case that the field combination of field set #B provides more bits than the number of configured SCells, some bits of the field combination are reserved as long as the remaining bits can provide sufficient bits for SCell dormancy indication. For example, as mentioned above, one or more bits in the bitmap based indicator formed by field set #B may be reserved, depending on a number of SCells configured for the UE. For example, assuming that N=2, the number of configured SCells=8 and cell #1 has a bandwidth requiring 10 bits for FDRA indication, according to example #B 1′, 2 (i.e., 10-8) bits in the bitmap based indicator may be reserved.

Generally, it is expected that the number of bits of the field combination of field set #B is not less than 15 or the number of SCells configured for the UE. However, in the case that the number of bits of the field combination of field set #B (e.g., the size of the bitmap based indicator) is less than the number of SCells configured for the UE, the bitmap based indicator may not be able to indicate dormancy for one or more SCells of the UE (e.g., SCells with highest SCell indexes), or alternatively, one bit in the field combination of field set #B may be used to indicate dormancy for a corresponding secondary cell group of the UE.

In some embodiments of the present disclosure, cell set #1 may include the PCell of a UE. When a multi-cell DCI format is used to indicate SCell dormancy for each configured SCell of a UE, this DCI format can schedule a data transmission on the PCell with valid value indicated in an FDRA field corresponding to the PCell. All FDRAs except the FDRA field for PCell indicates invalid value. The DCI format is transmitted on a PCell of the UE.

From the perspective of a UE, in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and all FDRA fields in the DCI format except the FDRA field for the PCell indicating invalid value, the UE can determine that a set of fields (denoted as field set #C) in the DCI format is repurposed for indicating secondary cell dormancy for each secondary cell of the UE; otherwise, the DCI format does not indicate per SCell dormancy for any secondary cell of the UE. From the perspective of a BS, depending on whether the DCI format is used to indicate dormancy for the secondary cell(s) of the UE, it can set the fields in the DCI format accordingly.

In some embodiments, fields in field set #C may be concatenated into an indicator (e.g., bitmap based indicator) according to a predefined rule, and each secondary cell of the UE corresponds to a respective bit in the bitmap based indicator. Details about the fields included in field set #C and the predefined rule for ordering these fields will be described later.

In some embodiments, the mapping relationship between the bits in the bitmap based indicator and the configured secondary cells of the UE may be predefined. In some embodiments, the configured SCells can be respectively mapped to the MSB to the LSB of the bitmap based indicator according to an ascending order of SCell indexes. For example, the MSB of the bitmap based indicator can indicate dormancy for the SCell with the lowest SCell index, the bit following the MSB can indicate dormancy for the SCell with the second lowest SCell index, and so on. In some embodiments, the configured SCells can be respectively mapped to the MSB to the LSB of the bitmap based indicator according to a descending order of SCell indexes. In some embodiments, the configured SCells can be respectively mapped to the LSB to the MSB of the bitmap based indicator according to an ascending order of SCell indexes. In some embodiments, the configured SCells can be respectively mapped to the LSB to the MSB of the bitmap based indicator according to a descending order of SCell indexes.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE. For example, assuming that the bitmap based indicator includes 16 bits and the UE is configured with 8 SCells, then 8 bits is sufficient for SCell dormancy indication. In some embodiments, the 8 MSBs of the bitmap based indicator can be used to indicate the SCell dormancy for the UE and the remaining bits in the bitmap based indicator can be ignored. In some embodiments, the 8 LSBs of the bitmap based indicator can be used to indicate the SCell dormancy for the UE and the remaining bits in the bitmap based indicator can be ignored.

A specific bit (denoted as bit #C) in the bitmap based indicator can be used to indicate dormancy for a corresponding secondary cell (denoted as cell #C) of the UE. In some embodiments, a value (e.g., ‘0’ or ‘1’) of bit #C may indicate the UE to switch to a dormant BWP of cell #C. Another value (e.g., ‘1’ or ‘0’) of bit #C may indicate the UE to switch to a first active BWP of cell #C in the case that current active BWP of cell #C is the dormant BWP or may indicate the UE to maintain the current active BWP of cell #C in the case that the current active BWP of cell #C is not the dormant BWP.

The DCI format may indicate a set of cells (e.g., cell set #2) among cell set #1 by, for example, a scheduled cell indicator in the DCI format if exists, otherwise cell set #2 is cell set #1. Cell set #2 may or may not include the PCell. Whether the PCell is scheduled by the DCI format or not or whether cell set #2 include the PCell or not can be determined based on whether a scheduled cell combination indicated by the DCI format (e.g., by the scheduled cell indicator) includes the PCell or not, or based on whether the FDRA field for the PCell indicates a valid or invalid value.

In the case that the DCI format is used to indicate SCell dormancy, the cell(s) in cell set #2 except the PCell (if included in cell set #2) is not actually scheduled by the DCI format. Fields specific for such a cell(s) can be repurposed for indicating secondary cell dormancy for each secondary cell of the UE. As the DCI format can schedule the PCell, field set #C does not include any field used for or specific the PCell. When, for example, the DCI format does not schedule a data transmission on the PCell, cell-common fields can be repurposed for secondary cell dormancy indication.

In some embodiments, field set #C may include one or more of fields in the DCI format: a cell-specific field with non-configurable field size (except a cell-specific field with non-configurable field size for the PCell if any); a cell-specific field with configurable field size (except a cell-specific field with configurable field size for the PCell if any); and a cell-common field.

Field set #C may not include an FDRA field. The number of FDRA fields (denoted as N) in the DCI format may be equal to the number of cells in cell set #2. In the case that a list of scheduled cell combinations is configured for the UE (e.g., via RRC signaling), the scheduled cell indicator in the DCI format may indicate a cell combination from the list of scheduled cell combinations. The indicated cell combination is cell set #2 and N is the number of cells in the indicated cell combination. As a special case, the list of scheduled cell combinations may include only one cell combination, then N is the number of cells in the single cell combination. In the case that the list of scheduled cell combinations is not configured for the UE, the DCI format does not include the scheduled cell indicator, then cell set #2 is cell set #1, and N is the number of cells in cell set #1. The N FDRA fields in the DCI format can be placed according to predefined order (e.g., an ascending or descending order) of the corresponding serving cell index of the cells in cell set #2. For example, when an ascending order of serving cell indexes is employed, the first FDRA field may correspond to the frequency domain resource assignment for the cell with the smallest serving cell index in cell set #2.

In some examples, field set #C may include a field(s) specifically used for a cell (e.g., one cell) with the smallest serving cell index among one or more cells within cell set #2 with corresponding FDRA fields in the DCI format indicating invalid value. In some examples, field set #C may include a field(s) specifically used for one or more cells with the smallest serving cell indexes among cell set #2 with corresponding FDRA fields in the DCI format indicating valid value.

Fields in field set #C can be ordered according to a predefined rule. For example, cell-specific fields in field set #C may be ordered in a cell index-first and field type-second order. For example, cell-specific fields in field set #C may be ordered in a field type-first and cell index-second order. The order of cell indexes here may refer to an ascending or descending order of cell indexes of the cells in cell set #2. Any other ordering method that can be conceived of by persons skilled in the art can apply.

The following shows some exemplary examples of field set #C and should not be construed as limiting the embodiments of the present disclosure. For simplicity, in the following examples, an ascending order of cell indexes is employed, it is assumed that cell set #2 does not include the PCell, and cells in cell set #2 are denoted as cell #1 to cell #N ordered according to the ascending order of cell indexes. In the case that cell set #2 includes the PCell, since PCell generally has the lowest serving cell index (e.g., 0), cell #1 is the PCell and cell-specific fields for cell #1 as described below will be excluded from field set #C.

In some examples, field set #C may only include cell-specific fields with non-configurable field size, which may be ordered according to a cell index-first and field type-second order. For example, field set #C may include an MCS field and an NDI field. For example, field set #C can be ordered as: {MCS of TB1 of cell #1, NDI of TB1 of cell #1, MCS of TB1 of cell #2, NDI of TB1 of Cell #2, . . . , MCS of TB1 of cell #N, NDI of TB1 of cell #N} (hereinafter, denoted as example #C1). In the case that cell #1 is the PCell, field set #C may be represented as: {MCS of TB1 of cell #2, NDI of TB1 of Cell #2, . . . , MCS of TB1 of cell #N, NDI of TB1 of cell #N}.

In some examples, field set #C may only include cell-specific fields with non-configurable field size, which may be ordered according to a field type-first and cell index-second order. For example, field set #C may include an MCS field and an NDI field. For example, field set #C can be ordered as: {MCS of TB1 of cell #1, MCS of TB1 of cell #2, . . . , MCS of TB1 of cell #N, NDI of TB1 of cell #1, NDI of TB1 of Cell #2, . . . , NDI of TB1 of cell #N} (hereinafter, denoted as example #C2). In the case that cell #1 is the PCell, field set #C may be represented as: {MCS of TB1 of cell #2, . . . , MCS of TB1 of cell #N, NDI of TB1 of Cell #2, . . . , NDI of TB1 of cell #N}.

In some examples, field set #C may include cell-specific fields with non-configurable and/or configurable field size, which may be ordered according to a cell index-first and field type-second order. For example, field set #C may include an MCS field, an NDI field, an RV field, a HARQ process number field, and an antenna port field (if configured as the cell-specific type). For example, field set #C can be ordered as: {MCS of TB1 of cell #1, NDI of TB1 of cell #1, RV of TB1 of cell #1, HARQ process number of cell #1, antenna port of cell #1 (if configured as the cell-specific type), MCS of TB1 of cell #2, NDI of TB1 of cell #2, RV of TB1 of cell #2, HARQ process number of cell #2, antenna port of cell #2 (if configured as the cell-specific type), . . . , MCS of TB1 of cell #N, NDI of TB1 of cell #N, RV of TB1 of cell #N, HARQ process number of cell #N, antenna port of cell #N (if configured as the cell-specific type) } (hereinafter, denoted as example #C3). In the case that cell #1 is the PCell, field set #C may be represented as: {MCS of TB1 of cell #2, NDI of TB1 of cell #2, RV of TB1 of cell #2, HARQ process number of cell #2, antenna port of cell #2(if configured as the cell-specific type), . . . , MCS of TB1 of cell #N, NDI of TB1 of cell #N, RV of TB1 of cell #N, HARQ process number of cell #N, antenna port of cell #N (if configured as the cell-specific type)}.

In some examples, field set #C may include cell-specific fields with non-configurable and/or configurable field size, which may be ordered according to a field type-first and cell index-second order. For example, field set #C may include an MCS field, an NDI field, an RV field, a HARQ process number field, and an antenna port field (if configured as the cell-specific type). For example, field set #C can be ordered as: {MCS of TB1 of cell #1, MCS of TB1 of cell #2, . . . , MCS of TB1 of cell #N, NDI of TB1 of cell #1, NDI of TB1 of cell #2, . . . , NDI of TB1 of cell #N, RV of TB1 of cell #1, RV of TB1 of cell #2, . . . , RV of TB1 of cell #N, HARQ process number of cell #1, HARQ process number of cell #2, . . . , HARQ process number of cell #N, antenna port of cell #1 (if configured as the cell-specific type), antenna port of cell #2 (if configured as the cell-specific type), . . . , antenna port of cell #N (if configured as the cell-specific type)} (hereinafter, denoted as example #C4). In the case that cell #1 is the PCell, field set #C may be represented as: {MCS of TB1 of cell #2, . . . , MCS of TB1 of cell #N, NDI of TB1 of cell #2, . . . , NDI of TB1 of cell #N, RV of TB1 of cell #2, . . . , RV of TB1 of cell #N, HARQ process number of cell #2, . . . , HARQ process number of cell #N, antenna port of cell #2 (if configured as the cell-specific type), . . . , antenna port of cell #N (if configured as the cell-specific type)}.

In the above examples, field set #C only includes cell-specific fields for TB1. It should be noted that field set #C may also include cell-specific fields for TB2 (if configured) in some other examples. For example, field set #C may include MCS of TB2, NDI of TB2, RV of TB2, or any combination thereof.

The UE may be configured with up to a maximum number of SCells. For clarity, it is assumed that the maximum number is equal to 15. It should be noted that the maximum number can be any other positive integer.

In some examples, in the case that the field combination of field set #C can provide more than 15 bits for SCell dormancy indication, some fields can be in field set #C can be excluded or reserved.

In some examples, in the case that the field combination of field set #C can provide more bits than the number of SCells configured for the UE, some fields can be in field set #C can be excluded or reserved.

Since the number of SCells configured for a UE is variable, in case that the field combination of field set #C provides more bits than the number of configured SCells, some bits of the field combination are reserved as long as the remaining bits can provide sufficient bits for SCell dormancy indication. For example, as mentioned above, one or more bits in the bitmap based indicator formed by field set #C may be reserved, depending on a number of SCells configured for the UE.

Generally, it is expected that the number of bits of the field combination of field set #C is not less than 15 or the number of SCells configured for the UE. However, in the case that the number of bits of the field combination of field set #C (e.g., the size of the bitmap based indicator) is less than the number of SCells configured for the UE, the bitmap based indicator may not be able to indicate dormancy for one or more SCells of the UE (e.g., SCells with highest SCell indexes), or alternatively, one bit in the field combination of field set #C may be used to indicate dormancy for a corresponding secondary cell group of the UE.

In some embodiments of the present disclosure, when a multi-cell DCI format is used to indicate SCell dormancy for each configured SCell of a UE, this DCI format is transmitted on the PCell and can schedule one or more data transmissions with valid value(s) indicated in the FDRA field(s) corresponding to the scheduled cell(s) among a set of cells (e.g., set #2) and invalid value indicated in the FDRA field(s) corresponding to the non-scheduled cell(s) among set #2. The DCI format may indicate cell set #2 among cell set #1 by, for example, a scheduled cell indicator in the DCI format if exists, otherwise cell set #2 is cell set #1.

For clarity, the one or more cells in cell set #2 but are not actually scheduled by the DCI format (e.g., the corresponding FDRA field of each of the one or more cells indicates an invalid value) are referred to as cell set #3. Cell set #3 may or may not include the PCell. In the case that the DCI format is used to indicate SCell dormancy, cells in cell set #3 are not actually scheduled by the DCI format and fields specific for cells in cell set #3 in the DCI format can be repurposed for indicating secondary cell dormancy for each secondary cell of the UE.

From the perspective of a UE, in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and at least one FDRA field in the DCI format indicating an invalid value, the UE can determine that a set of fields (denoted as field set #D) in the DCI format is repurposed for indicating secondary cell dormancy for each secondary cell of the UE; otherwise, in response to the one-shot HARQ-ACK request field indicating that one-shot HARQ-ACK feedback is triggered, or a HARQ-ACK retransmission indicator indicating HARQ-ACK retransmission, or all FDRA fields in the DCI format indicating a valid value, the UE can determine that the DCI format does not indicate per SCell dormancy for any secondary cell of the UE. From the perspective of a BS, depending on whether the DCI format is used to indicate dormancy for the secondary cell(s) of the UE, it can set the fields in the DCI format accordingly.

In some embodiments, fields in field set #D may be concatenated into an indicator (e.g., bitmap based indicator) according to a predefined rule, and each secondary cell of the UE corresponds to a respective bit in the bitmap based indicator. Details about the fields included in field set #D and the predefined rule for ordering these fields will be described later.

In some embodiments, the mapping relationship between the bits in the bitmap based indicator and the configured secondary cells of the UE may be predefined. In some embodiments, the configured SCells can be respectively mapped to the MSB to the LSB of the bitmap based indicator according to an ascending order of SCell indexes. For example, the MSB of the bitmap based indicator can indicate dormancy for the SCell with the lowest SCell index, the bit following the MSB can indicate dormancy for the SCell with the second lowest SCell index, and so on. In some embodiments, the configured SCells can be respectively mapped to the MSB to the LSB of the bitmap based indicator according to a descending order of SCell indexes. In some embodiments, the configured SCells can be respectively mapped to the LSB to the MSB of the bitmap based indicator according to an ascending order of SCell indexes. In some embodiments, the configured SCells can be respectively mapped to the LSB to the MSB of the bitmap based indicator according to a descending order of SCell indexes.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE. For example, assuming that the bitmap based indicator includes 16 bits and the UE is configured with 8 SCells, then 8 bits is sufficient for SCell dormancy indication. In some embodiments, the 8 MSBs of the bitmap based indicator can be used to indicate the SCell dormancy for the UE and the remaining bits in the bitmap based indicator can be ignored. In some embodiments, the 8 LSBs of the bitmap based indicator can be used to indicate the SCell dormancy for the UE and the remaining bits in the bitmap based indicator can be ignored.

A specific bit (denoted as bit #D) in the bitmap based indicator can be used to indicate dormancy for a corresponding secondary cell (denoted as cell #D) of the UE. In some embodiments, a value (e.g., ‘0’ or ‘1’) of bit #D may indicate the UE to switch to a dormant BWP of cell #D. Another value (e.g., ‘1’ or ‘0’) of bit #D may indicate the UE to switch to a first active BWP of cell #D in the case that current active BWP of cell #D is the dormant BWP or may indicate the UE to maintain the current active BWP of cell #D in the case that the current active BWP of cell #D is not the dormant BWP.

Fields specific for cells in cell set #3 in the DCI format can be repurposed for indicating secondary cell dormancy for each secondary cell of the UE. When, for example, the DCI format does not schedule any data transmission cell-common fields can be repurposed for secondary cell dormancy indication.

In some embodiments, field set #D may include one or more of fields in the DCI format: a cell-specific field with non-configurable field size for a non-scheduled cell (e.g., a cell in cell set #3); a cell-specific field with configurable field size for a non-scheduled cell (e.g., a cell in cell set #3); and a cell-common field.

Field set #D may not include an FDRA field. The number of FDRA fields (e.g., N) in the DCI format may be equal to the number of cells in cell set #2. In the case that a list of scheduled cell combinations is configured for the UE (e.g., via RRC signaling), the scheduled cell indicator in the DCI format may indicate a cell combination from the list of scheduled cell combinations. The indicated cell combination is cell set #2 and N is the number of cells in the indicated cell combination. As a special case, the list of scheduled cell combinations may include only one cell combination, then N is the number of cells in the single cell combination. In the case that the list of scheduled cell combinations is not configured for the UE, the DCI format does not include the scheduled cell indicator, then cell set #2 is cell set #1, and N is the number of cells in cell set #1. The N FDRA fields in the DCI format can be placed according to predefined order (e.g., an ascending or descending order) of the corresponding serving cell index of the cells in cell set #2. For example, when an ascending order of serving cell indexes is employed, the first FDRA field may correspond to the frequency domain resource assignment for the cell with the smallest serving cell index in cell set #2. The number of cell in cell set #3 (denoted as N′) is dependent on (e.g., equal to) the number of FDRA fields in the DCI format indicating invalid values.

In some examples, field set #D may include a field(s) specifically used for a cell (e.g., one cell) with the smallest serving cell index among one or more cells within cell set #3 with corresponding FDRA fields in the DCI format indicating invalid value. In some examples, field set #D may include a field(s) specifically used for one or more cells with the smallest serving cell indexes among cell set #3 with corresponding FDRA fields in the DCI format indicating valid value.

Fields in field set #D can be ordered according to a predefined rule. For example, cell-specific fields in field set #D may be ordered in a cell index-first and field type-second order. For example, cell-specific fields in field set #D may be ordered in a field type-first and cell index-second order. The order of cell indexes here may refer to an ascending or descending order of cell indexes of the cells in cell set #3. Any other ordering method that can be conceived of by persons skilled in the art can apply.

The following shows some exemplary examples of field set #D and should not be construed as limiting the embodiments of the present disclosure. For simplicity, in the following examples, an ascending order of cell indexes is employed and cells in cell set #3 are denoted as cell #1′ to cell #N′ ordered according to the ascending order of cell indexes.

In some examples, field set #D may only include cell-specific fields with non-configurable field size, which may be ordered according to a cell index-first and field type-second order. For example, field set #D may include an MCS field and an NDI field. For example, field set #D can be ordered as: {MCS of TB1 of cell #1′, NDI of TB1 of cell #1′, MCS of TB1 of cell #2′, NDI of TB1 of Cell #2′, . . . , MCS of TB1 of cell #N′, NDI of TB1 of cell #N′} (hereinafter, denoted as example #D1).

In some examples, field set #D may only include cell-specific fields with non-configurable field size, which may be ordered according to a field type-first and cell index-second order. For example, field set #D may include an MCS field and an NDI field. For example, field set #D can be ordered as: {MCS of TB1 of cell #1′, MCS of TB1 of cell #2′, . . . , MCS of TB1 of cell #N′, NDI of TB1 of cell #1′, NDI of TB1 of Cell #2′, . . . , NDI of TB1 of cell #N′} (hereinafter, denoted as example #D2).

In some examples, field set #D may include cell-specific fields with non-configurable and/or configurable field size, which may be ordered according to a cell index-first and field type-second order. For example, field set #D may include an MCS field, an NDI field, an RV field, a HARQ process number field, and an antenna port field (if configured as the cell-specific type). For example, field set #D can be ordered as: {MCS of TB1 of cell #1′, NDI of TB1 of cell #1′, RV of TB1 of cell #1′, HARQ process number of cell #1′, antenna port of cell #1′ (if configured as the cell-specific type), MCS of TB1 of cell #2′, NDI of TB1 of cell #2′, RV of TB1 of cell #2′, HARQ process number of cell #2′, antenna port of cell #2′ (if configured as the cell-specific type), . . . , MCS of TB1 of cell #N′, NDI of TB1 of cell #N′, RV of TB1 of cell #N′, HARQ process number of cell #N′, antenna port of cell #N′ (if configured as the cell-specific type)} (hereinafter, denoted as example #D3).

In some examples, field set #D may include cell-specific fields with non-configurable and/or configurable field size, which may be ordered according to a field type-first and cell index-second order. For example, field set #D may include an MCS field, an NDI field, an RV field, a HARQ process number field, and an antenna port field (if configured as the cell-specific type). For example, field set #D can be ordered as: {MCS of TB1 of cell #1′, MCS of TB1 of cell #2′, . . . , MCS of TB1 of cell #N′, NDI of TB1 of cell #1′, NDI of TB1 of cell #2′, . . . , NDI of TB1 of cell #N′, RV of TB1 of cell #1′, RV of TB1 of cell #2′, . . . , RV of TB1 of cell #N′, HARQ process number of cell #1′, HARQ process number of cell #2′,. HARQ process number of cell #N′, antenna port of cell #1′ (if configured as the cell-specific type), antenna port of cell #2′ (if configured as the cell-specific type), . . . , antenna port of cell #N′ (if configured as the cell-specific type)} (hereinafter, denoted as example #D4).

In the above examples, field set #D only includes cell-specific fields for TB1. It should be noted that field set #D may also include cell-specific fields for TB2 (if configured) in some other examples. For example, field set #D may include MCS of TB2, NDI of TB2, RV of TB2, or any combination thereof.

In some embodiments, the number of FDRA fields indicating invalid values or the number of cells in cell set #3 (i.e., the value of N′) may be determined based on a number of secondary cells configured for the UE. For example, the BS can determine the number of bits required for secondary cell dormancy indication based on the number of secondary cells configured for the UE. If the cell-specific field(s) for a single cell is sufficient to indicate the secondary cell dormancy for each secondary cell of the UE, the BS may set the DCI format such that cell set #3 include only a single cell with corresponding FDRA field indicating an invalid value and FDRA fields of other cells in cell set #2 are indicated with valid values. In some examples, there may be more than one cell in cell set #3, i.e., more than one cell are indicated with invalid FDRA values, then in field set #D, the field specific for the cell with the smallest or highest cell index among cell set #3 is repurposed for indicating SCell dormancy for each SCell of the UE. If the cell-specific field(s) for one cell is not sufficient, the BS can determine the number of cells in cell set #3 or the number of FDRA fields indicating invalid value according to the number of secondary cells configured for the UE. For example, if the cell-specific fields for two cells are sufficient, cell set #3 may include two cells with corresponding FDRA fields indicating invalid value and FDRA fields of other cells in cell set #2 are indicated with valid values. In some examples, there may be more than two cells in cell set #3, i.e., more than two cells are indicated with invalid FDRA values, and then in field set #D, the field specific for two cells with the smallest or highest cell indexes among cell set #3 is repurposed for indicating SCell dormancy for each SCell of the UE.

The UE may be configured with up to a maximum number of SCells. For clarity, it is assumed that the maximum number is equal to 15. It should be noted that the maximum number can be any other positive integer.

In some examples, in the case that the field combination of field set #D can provide more than 15 bits for SCell dormancy indication, some fields can be in field set #D can be excluded or reserved.

For example, in example #D3, the total bits of {MCS of TB1 of cell #1′ (e.g., 5 bits), NDI of TB1 of cell #1′ (e.g., 1 bit), RV of TB1 of cell #1′ (e.g., 2 bits), HARQ process number of cell #1′ (e.g., 4 bits), antenna port of cell #1′ (if configured as the cell-specific type) (e.g., 4 bits)} may be equal to 16 bits. In the case that N′>1, field set #D may only include cell-specific fields for cell #1′ (i.e., the cell with the smallest serving cell index in cell set #3) and does not need to include those for cells with larger serving cell indexes in cell set #3 (e.g., cell #2′ to cell #N′). That is, field set #D may not need to include {MCS of TB1 of cell #2′, NDI of TB1 of cell #2′, RV of TB1 of cell #2′, HARQ process number of cell #2′, antenna port of cell #2′ (if configured as the cell-specific type), . . . , MCS of TB1 of cell #N′, NDI of TB1 of cell #N′, RV of TB1 of cell #N′, HARQ process number of cell #N′, antenna port of cell #N′ (if configured as the cell-specific type)}. That is, field set #D may include {MCS of TB1 of cell #1′, NDI of TB1 of cell #1′, RV of TB1 of cell #1′, HARQ process number of cell #1′, antenna port of cell #1′ (if configured as the cell-specific type)} (hereinafter, denoted as example #D3′).

In the case that cells in cell set #3 are ordered according to the descending order of cell indexes for secondary cell dormancy indication, field set #D under example #D3 can be modified as: {MCS of TB1 of cell #N′, NDI of TB1 of cell #N′, RV of TB1 of cell #N′, HARQ process number of cell #N′, antenna port of cell #N′ (if configured as the cell-specific type), . . . , MCS of TB1 of cell #2′, NDI of TB1 of cell #2′, RV of TB1 of cell #2′, HARQ process number of cell #2′, antenna port of cell #2′ (if configured as the cell-specific type), MCS of TB1 of cell #1′, NDI of TB1 of cell #1′, RV of TB1 of cell #1′, HARQ process number of cell #1′, antenna port of cell #1′ (if configured as the cell-specific type)}. Since cell-specific fields for cell #N′ (i.e., the cell with the largest serving cell index in cell set #3) is sufficient to indicate secondary cell dormancy for each secondary cell of the UE, that is, bit number is 16 which is larger than 15, field set #D may only include cell-specific fields for cell #N′ (i.e., the cell with the largest serving cell index in cell set #3) and does not need to include those for cells with smaller serving cell indexes in cell set #3. That is, field set #D may include {MCS of TB1 of cell #N′, NDI of TB1 of cell #N′, RV of TB1 of cell #N′, HARQ process number of cell #N′, antenna port of cell #N′ (if configured as the cell-specific type)}

However, if the cell-specific field(s) for cell #1′ (or cell N′) is not sufficient to indicate secondary cell dormancy for each secondary cell of the UE, field set #D may further include a cell-specific field(s) for a cell(s) with a larger (or smaller) serving cell index(es) in cell set #3. For example, field set #D may include cell-specific fields for cells with the smallest and second smallest serving cell indexes in cell set #3. For example, field set #D may include cell-specific fields for cells with the largest and second largest serving cell indexes in cell set #3.

The above principle can be readily applied to other examples or embodiments in the present disclosure by persons skilled in the art.

In some examples, in the case that the field combination of field set #D can provide more bits than the number of SCells configured for the UE, some fields can be in field set #D can be excluded or reserved.

For example, assuming that N′=2 and the number of configured SCells=8, the total bits of field set #D in example #D 1 may be equal to 12 bits. Therefore, field set #D may not need to include {NDI of TB1 of Cell #2′ (e.g., 1 bit)}. Field set #D may include {MCS of TB1 of cell #1′ (e.g., 5 bits), NDI of TB1 of cell #1′ (e.g., 1 bit), MCS of TB1 of cell #2′ (e.g., 5 bits)} (hereinafter, denoted as example #D 1′), and thus provide 11 bits which is larger than the number of configured SCells (i.e., 8).

Since the number of SCells configured for a UE is variable, in case that the field combination of field set #D provides more bits than the number of configured SCells, some bits of the field combination are reserved as long as the remaining bits can provide sufficient bits for SCell dormancy indication. For example, as mentioned above, one or more bits in the bitmap based indicator formed by field set #D may be reserved, depending on a number of SCells configured for the UE. For example, assuming that N′=2 and the number of configured SCells=8, according to example #D 1′, 3 (i.e., 11-8) bits in the bitmap based indicator may be reserved.

Generally, it is expected that the number of bits of the field combination of field set #D is not less than 15 or the number of SCells configured for the UE. However, in the case that the number of bits of the field combination of field set #D (e.g., the size of the bitmap based indicator) is less than the number of SCells configured for the UE, the bitmap based indicator may not be able to indicate dormancy for one or more SCells of the UE (e.g., SCells with highest SCell indexes), or alternatively, one bit in the field combination of field set #D may be used to indicate dormancy for a corresponding secondary cell group of the UE.

FIG. 3 illustrates a flowchart of method 300 for wireless communication in accordance with some embodiments of the present disclosure. Details described in all of the foregoing embodiments of the present disclosure are applicable for the embodiments shown in FIG. 3. In some examples, method 300 may be performed by a UE, for example, UE 104 as described with reference to FIG. 1. In some embodiments, the UE may execute a set of instructions to control the functional elements of the UE to perform the described functions or operations. In some examples, a processor of a UE may cause the UE to perform method 300.

At 311, a UE may receive, from a BS, a signaling configuring a first set of cells for multi-cell scheduling by a DCI format and CRC of the DCI format is scrambled by a C-RNTI or an MCS-C-RNTI of the UE. At 313, the UE may receive the DCI format from the BS. At 315, the UE may determine whether a set of fields in the DCI format is repurposed for indicating secondary cell dormancy for each secondary cell of the UE, wherein a first bit of the set of fields corresponds to a first secondary cell of the UE. At 317, the UE may switch to a dormant BWP of the first secondary cell of the UE in response to the first bit indicating dormancy for the first secondary cell.

In some embodiments, the UE may determine that the set of fields in the DCI format is repurposed for indicating secondary cell dormancy for each secondary cell of the UE in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and all FDRA fields in the DCI format indicating invalid value.

In some embodiments, the DCI may include a first indicator indicating whether the set of fields in the DCI format is repurposed for indicating secondary cell dormancy for each secondary cell of the UE, or a second indicator in the DCI format is used for indicating secondary cell dormancy for each secondary cell group of the UE.

In some embodiments, in the case that the first indicator indicates the set of fields in the DCI format being repurposed for indicating secondary cell dormancy for each secondary cell of the UE, the DCI format does not schedule any data transmission. In some embodiments, in the case that the first indicator indicates the second indicator in the DCI format being used for indicating secondary cell dormancy for each secondary cell group of the UE, the DCI format schedules one or more data transmissions for the UE.

In some embodiments, the set of fields may include one or more FDRA fields corresponding to one or more cells with smallest serving cell indices among a second set of cells. In some embodiments, the second set of cells is indicated by the DCI format among the first set of cells in response to the DCI format including an indicator indicating scheduled cells, otherwise the second set of cells is the first set of cells.

In some embodiments, the first set of cells may include a primary cell of the UE. The UE may determine that the set of fields in the DCI format is repurposed for indicating secondary cell dormancy for each secondary cell of the UE in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and all FDRA fields in the DCI format except a FDRA field for the primary cell indicating invalid value.

In some embodiments, the set of fields does not include a field used for the primary cell.

In some embodiments, the UE may determine whether the primary cell is scheduled by the DCI format based on whether the FDRA field for the primary cell indicates a valid value or invalid value or based on whether a scheduled cell combination indicated by the DCI format includes the primary cell or not.

In some embodiments, the UE may determine that the set of fields in the DCI format is repurposed for indicating secondary cell dormancy for each secondary cell of the UE in response to a one-shot HARQ-ACK request field being absent from the DCI format or indicating that one-shot HARQ-ACK feedback is not triggered, a HARQ-ACK retransmission indicator being absent from the DCI format or indicating that HARQ-ACK retransmission is not triggered, and at least one FDRA field in the DCI format indicating an invalid value.

In some embodiments, the number of the at least one FDRA field is determined based on a number of secondary cells configured for the UE.

In some embodiments, the set of fields is specifically used for a cell with a smallest serving cell index among one or more cells within a second set of cells with corresponding FDRA fields in the DCI format indicating invalid value. In some embodiments, the second set of cells is indicated by the DCI format among the first set of cells in response to the DCI format including an indicator indicating scheduled cells, otherwise the second set of cells is the first set of cells.

In some embodiments, the set of fields are concatenated into a bitmap based indicator according to a predefined rule, and each secondary cell of the UE corresponds to a respective bit in the bitmap based indicator.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE.

In some embodiments, a first value of the first bit may indicate the UE to switch to the dormant BWP of the first secondary cell. In some embodiments, a second value of the first bit may indicate the UE to switch to a first active BWP of the first secondary cell in the case that current active BWP of the first secondary cell is the dormant BWP or may indicate the UE to maintain the current active BWP of the first secondary cell in the case that the current active BWP of the first secondary cell is not the dormant BWP.

In some embodiments, the set of fields may include one or more of the following: a cell-specific field with non-configurable field size; a cell-specific field with configurable field size; and a cell-common field.

It should be appreciated by persons skilled in the art that the sequence of the operations in exemplary method 300 may be changed and some of the operations in exemplary method 300 may be eliminated or modified, without departing from the spirit and scope of the disclosure.

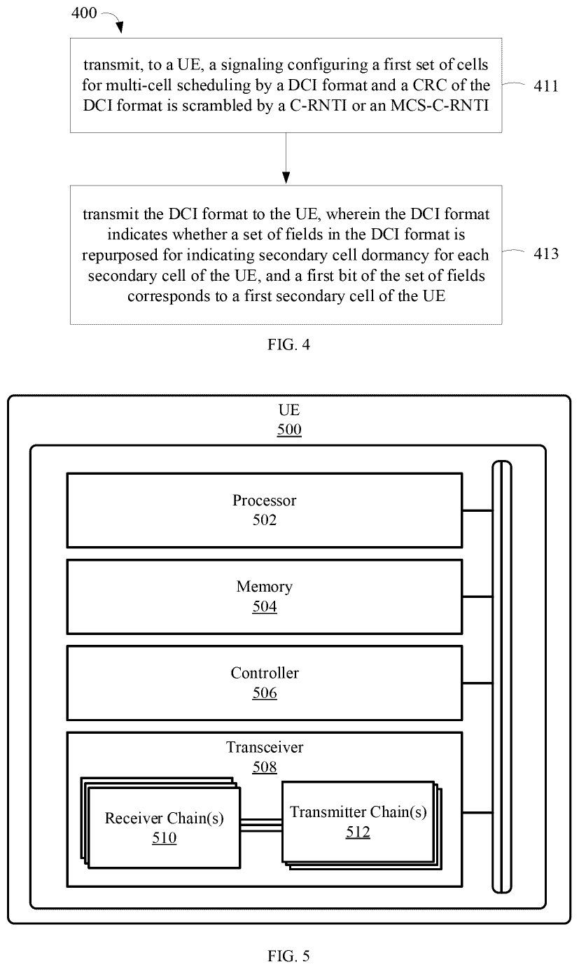

FIG. 4 illustrates a flowchart of method 400 for wireless communication in accordance with some embodiments of the present disclosure. Details described in all of the foregoing embodiments of the present disclosure are applicable for the embodiments shown in FIG. 4. In some examples, method 400 may be performed by a BS or an NE (for example, NE 102 as described with reference to FIG. 1). In some embodiments, the BS or the NE may execute a set of instructions to control the functional elements of the BS or the NE to perform the described functions or operations. In some examples, a processor of an NE may cause the NE to perform method 400.

At 411, a BS may transmit, to a UE, a signaling configuring a first set of cells for multi-cell scheduling by a DCI format and CRC of the DCI format is scrambled by a C-RNTI or an MCS-C-RNTI of the UE. At 413, the BS may transmit the DCI format to the UE, wherein the DCI format indicates whether a set of fields in the DCI format is repurposed for indicating secondary cell dormancy for each secondary cell of the UE, and a first bit of the set of fields corresponds to a first secondary cell of the UE.

In some embodiments, in the case that a one-shot HARQ-ACK request field is absent from the DCI format or indicates that one-shot HARQ-ACK feedback is not triggered, a HARQ-ACK retransmission indicator is absent from the DCI format or indicates that HARQ-ACK retransmission is not triggered, and all FDRA fields in the DCI format indicates invalid value, the set of fields in the DCI format is repurposed for indicating secondary cell dormancy for each secondary cell of the UE.

In some embodiments, the DCI may include a first indicator indicating whether the set of fields in the DCI format is repurposed for indicating secondary cell dormancy for each secondary cell of the UE, or a second indicator in the DCI format is used for indicating secondary cell dormancy for each secondary cell group of the UE.

In some embodiments, in the case that the first indicator indicates that the set of fields in the DCI format is repurposed for indicating secondary cell dormancy for each secondary cell of the UE, the DCI format does not schedule any data transmission. In some embodiments, in the case that the first indicator indicates that the second indicator in the DCI format is used for indicating secondary cell dormancy for each secondary cell group of the UE, the DCI format schedules one or more data transmissions for the UE.

In some embodiments, the set of fields may include one or more FDRA fields corresponding to one or more cells with smallest serving cell indices among a second set of cells. In some embodiments, the second set of cells is indicated by the DCI format among the first set of cells in response to the DCI format including an indicator indicating scheduled cells, otherwise the second set of cells is the first set of cells.

In some embodiments, the first set of cells may include a primary cell of the UE. In some embodiments, in the case that a one-shot HARQ-ACK request field is absent from the DCI format or indicates that one-shot HARQ-ACK feedback is not triggered, a HARQ-ACK retransmission indicator is absent from the DCI format or indicates that HARQ-ACK retransmission is not triggered, and all FDRA fields in the DCI format except a FDRA field for the primary cell indicates invalid value, the set of fields in the DCI format is repurposed for indicating secondary cell dormancy for each secondary cell of the UE.

In some embodiments, the set of fields does not include a field used for the primary cell.

In some embodiments, whether the primary cell is scheduled by the DCI format or not is based on whether the FDRA field for the primary cell indicates a valid value or invalid value or based on whether a scheduled cell combination indicated by the DCI format includes the primary cell or not.

In some embodiments, in the case that a one-shot HARQ-ACK request field is absent from the DCI format or indicates that one-shot HARQ-ACK feedback is not triggered, a HARQ-ACK retransmission indicator is absent from the DCI format or indicates that HARQ-ACK retransmission is not triggered, and at least one FDRA field in the DCI format indicates an invalid value, the set of fields in the DCI format is repurposed for indicating secondary cell dormancy for each secondary cell of the UE.

In some embodiments, the BS may determine the number of the at least one FDRA field based on a number of secondary cells configured for the UE.

In some embodiments, the set of fields is specifically used for a cell with a smallest serving cell index among one or more cells within a second set of cells with corresponding FDRA fields in the DCI format indicating invalid value. In some embodiments, the second set of cells is indicated by the DCI format among the first set of cells in response to the DCI format including an indicator indicating scheduled cells, otherwise the second set of cells is the first set of cells.

In some embodiments, the set of fields are concatenated into a bitmap based indicator according to a predefined rule, and each secondary cell of the UE corresponds to a respective bit in the bitmap based indicator.

In some embodiments, a plurality of bits in the bitmap based indicator is used to indicate the dormancy for each secondary cell of the UE and the remaining bit(s) in the bitmap based indicator is reserved, depending on a number of secondary cells configured for the UE.

In some embodiments, a first value of the first bit may indicate the UE to switch to a dormant BWP of the first secondary cell. In some embodiments, a second value of the first bit may indicate the UE to switch to a first active BWP of the first secondary cell in the case that current active BWP of the first secondary cell is the dormant BWP or may indicate the UE to maintain the current active BWP of the first secondary cell in the case that the current active BWP of the first secondary cell is not the dormant BWP.

In some embodiments, the set of fields may include one or more of the following: a cell-specific field with non-configurable field size; a cell-specific field with configurable field size; and a cell-common field.

It should be appreciated by persons skilled in the art that the sequence of the operations in exemplary method 400 may be changed and some of the operations in exemplary method 400 may be eliminated or modified, without departing from the spirit and scope of the disclosure.

FIG. 5 illustrates an example of a UE 500 in accordance with aspects of the present disclosure. The UE 500 may include a processor 502, a memory 504, a controller 506, and a transceiver 508. The processor 502, the memory 504, the controller 506, or the transceiver 508, or various combinations thereof or various components thereof may be examples of means for performing various aspects of the present disclosure as described herein. These components may be coupled (e.g., operatively, communicatively, functionally, electronically, electrically) via one or more interfaces.

The processor 502, the memory 504, the controller 506, or the transceiver 508, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 502 may include an intelligent hardware device (e.g., a general-purpose processor, a DSP, a CPU, an ASIC, an FPGA, or any combination thereof). In some implementations, the processor 502 may be configured to operate the memory 504. In some other implementations, the memory 504 may be integrated into the processor 502. The processor 502 may be configured to execute computer-readable instructions stored in the memory 504 to cause the UE 500 to perform various functions of the present disclosure.

The memory 504 may include volatile or non-volatile memory. The memory 504 may store computer-readable, computer-executable code including instructions when executed by the processor 502 cause the UE 500 to perform various functions described herein. The code may be stored in a non-transitory computer-readable medium such as the memory 504 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 502 and the memory 504 coupled with the processor 502 may be configured to cause the UE 500 to perform one or more of the functions described herein (e.g., executing, by the processor 502, instructions stored in the memory 504). For example, the processor 502 may support wireless communication at the UE 500 in accordance with examples as disclosed herein. For example, the UE 500 may be configured to support means for performing the operations as described with respect to FIG. 3.

For example, the UE 500 may be configured to support: a means for receiving, from a BS, a signaling configuring a first set of cells for multi-cell scheduling by a DCI format and CRC of the DCI format is scrambled by a C-RNTI or an MCS-C-RNTI of the UE 500; a means for receiving the DCI format from the BS; a means for determining whether a set of fields in the DCI format is repurposed for indicating secondary cell dormancy for each secondary cell of the UE 500, wherein a first bit of the set of fields corresponds to a first secondary cell of the UE 500; and a means for switching to a dormant BWP of the first secondary cell of the UE 500 in response to the first bit indicating dormancy for the first secondary cell.

The controller 506 may manage input and output signals for the UE 500. The controller 506 may also manage peripherals not integrated into the UE 500. In some implementations, the controller 506 may utilize an operating system such as iOS®, ANDROID®, WINDOWS®, or other operating systems. In some implementations, the controller 506 may be implemented as part of the processor 502.

In some implementations, the UE 500 may include at least one transceiver 508. In some other implementations, the UE 500 may have more than one transceiver 508. The transceiver 508 may represent a wireless transceiver. The transceiver 508 may include one or more receiver chains 510, one or more transmitter chains 512, or a combination thereof.

A receiver chain 510 may be configured to receive signals (e.g., control information, data, or packets) over a wireless medium. For example, the receiver chain 510 may include one or more antennas for receive the signal over the air or wireless medium. The receiver chain 510 may include at least one amplifier (e.g., a low-noise amplifier (LNA)) configured to amplify the received signal. The receiver chain 510 may include at least one demodulator configured to demodulate the receive signal and obtain the transmitted data by reversing the modulation technique applied during transmission of the signal. The receiver chain 510 may include at least one decoder for decoding the processing the demodulated signal to receive the transmitted data.

A transmitter chain 512 may be configured to generate and transmit signals (e.g., control information, data, or packets). The transmitter chain 512 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 512 may also include at least one power amplifier configured to amplify the modulated signal to an appropriate power level suitable for transmission over the wireless medium. The transmitter chain 512 may also include one or more antennas for transmitting the amplified signal into the air or wireless medium.

It should be appreciated by persons skilled in the art that the components in exemplary UE 500 may be changed, for example, some of the components in exemplary UE 500 may be omitted or modified or a new component(s) may be added to exemplary UE 500, without departing from the spirit and scope of the disclosure. For example, in some embodiments, the UE 500 may not include the controller 506.

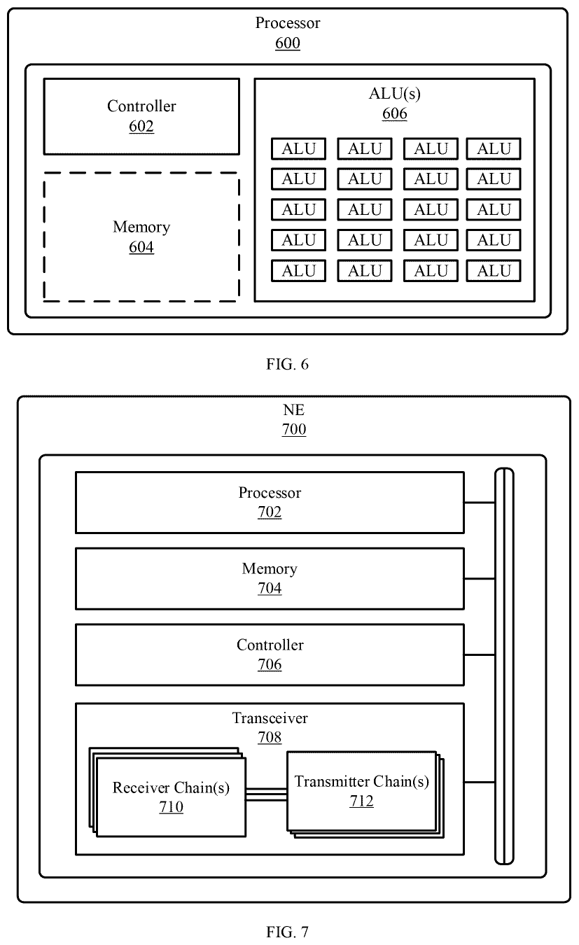

FIG. 6 illustrates an example of a processor 600 in accordance with aspects of the present disclosure. The processor 600 may be an example of a processor configured to perform various operations in accordance with examples as described herein. The processor 600 may include a controller 602 configured to perform various operations in accordance with examples as described herein. The processor 600 may optionally include at least one memory 604, which may be, for example, an L1/L2/L3 cache. Additionally, or alternatively, the processor 600 may optionally include one or more arithmetic-logic units (ALUs) 606. One or more of these components may be in electronic communication or otherwise coupled (e.g., operatively, communicatively, functionally, electronically, electrically) via one or more interfaces (e.g., buses).

The processor 600 may be a processor chipset and include a protocol stack (e.g., a software stack) executed by the processor chipset to perform various operations (e.g., receiving, obtaining, retrieving, transmitting, outputting, forwarding, storing, determining, identifying, accessing, writing, reading) in accordance with examples as described herein. The processor chipset may include one or more cores, one or more caches (e.g., memory local to or included in the processor chipset (e.g., the processor 600) or other memory (e.g., random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others).

The controller 602 may be configured to manage and coordinate various operations (e.g., signaling, receiving, obtaining, retrieving, transmitting, outputting, forwarding, storing, determining, identifying, accessing, writing, reading) of the processor 600 to cause the processor 600 to support various operations in accordance with examples as described herein. For example, the controller 602 may operate as a control unit of the processor 600, generating control signals that manage the operation of various components of the processor 600. These control signals include enabling or disabling functional units, selecting data paths, initiating memory access, and coordinating timing of operations.

The controller 602 may be configured to fetch (e.g., obtain, retrieve, receive) instructions from the memory 604 and determine a subsequent instruction(s) to be executed to cause the processor 600 to support various operations in accordance with examples as described herein. The controller 602 may be configured to track memory address of instructions associated with the memory 604. The controller 602 may be configured to decode instructions to determine the operation to be performed and the operands involved. For example, the controller 602 may be configured to interpret the instruction and determine control signals to be output to other components of the processor 600 to cause the processor 600 to support various operations in accordance with examples as described herein. Additionally, or alternatively, the controller 602 may be configured to manage flow of data within the processor 600. The controller 602 may be configured to control transfer of data between registers, ALUs, and other functional units of the processor 600.

The memory 604 may include one or more caches (e.g., memory local to or included in the processor 600 or other memory, such RAM, ROM, DRAM, SDRAM, SRAM, MRAM, flash memory, etc. In some implementations, the memory 604 may reside within or on a processor chipset (e.g., local to the processor 600). In some other implementations, the memory 604 may reside external to the processor chipset (e.g., remote to the processor 600).

The memory 604 may store computer-readable, computer-executable code including instructions that, when executed by the processor 600, cause the processor 600 to perform various functions described herein. The code may be stored in a non-transitory computer-readable medium such as system memory or another type of memory. The controller 602 and/or the processor 600 may be configured to execute computer-readable instructions stored in the memory 604 to cause the processor 600 to perform various functions. For example, the processor 600 and/or the controller 602 may be coupled with or to the memory 604, the processor 600, the controller 602, and the memory 604 may be configured to perform various functions described herein. In some examples, the processor 600 may include multiple processors and the memory 604 may include multiple memories. One or more of the multiple processors may be coupled with one or more of the multiple memories, which may, individually or collectively, be configured to perform various functions herein.

The one or more ALUs 606 may be configured to support various operations in accordance with examples as described herein. In some implementations, the one or more ALUs 606 may reside within or on a processor chipset (e.g., the processor 600). In some other implementations, the one or more ALUs 606 may reside external to the processor chipset (e.g., the processor 600). One or more ALUs 606 may perform one or more computations such as addition, subtraction, multiplication, and division on data. For example, one or more ALUs 606 may receive input operands and an operation code, which determines an operation to be executed. One or more ALUs 606 be configured with a variety of logical and arithmetic circuits, including adders, subtractors, shifters, and logic gates, to process and manipulate the data according to the operation. Additionally, or alternatively, the one or more ALUs 606 may support logical operations such as AND, OR, exclusive-OR (XOR), not-OR (NOR), and not-AND (NAND), enabling the one or more ALUs 606 to handle conditional operations, comparisons, and bitwise operations.

The processor 600 may support wireless communication in accordance with examples as disclosed herein.

For example, the processor 600 may be configured to support means for performing the operations as described with respect to FIG. 3. For example, the processor 600 may be configured to or operable to support: a means for receiving, from a BS, a signaling configuring a first set of cells for multi-cell scheduling by a DCI format and CRC of the DCI format is scrambled by a C-RNTI or an MCS-C-RNTI of a UE; a means for receiving the DCI format from the BS; a means for determining whether a set of fields in the DCI format is repurposed for indicating secondary cell dormancy for each secondary cell of the UE, wherein a first bit of the set of fields corresponds to a first secondary cell of the UE; and a means for switching to a dormant BWP of the first secondary cell of the UE in response to the first bit indicating dormancy for the first secondary cell.

For example, the processor 600 may be configured to support means for performing the operations as described with respect to FIG. 4. For example, the processor 600 may be configured to support: a means for transmitting, to a UE, a signaling configuring a first set of cells for multi-cell scheduling by a DCI format and CRC of the DCI format is scrambled by a C-RNTI or an MCS-C-RNTI of the UE; and a means for transmitting the DCI format to the UE, wherein the DCI format may indicate whether a set of fields in the DCI format is repurposed for indicating secondary cell dormancy for each secondary cell of the UE, and a first bit of the set of fields corresponds to a first secondary cell of the UE.

It should be appreciated by persons skilled in the art that the components in exemplary processor 600 may be changed, for example, some of the components in exemplary processor 600 may be omitted or modified or a new component(s) may be added to exemplary processor 600, without departing from the spirit and scope of the disclosure. For example, in some embodiments, the processor 600 may not include the ALUs 606.

FIG. 7 illustrates an example of an NE 700 in accordance with aspects of the present disclosure. The NE 700 may include a processor 702, a memory 704, a controller 706, and a transceiver 708. The processor 702, the memory 704, the controller 706, or the transceiver 708, or various combinations thereof or various components thereof may be examples of means for performing various aspects of the present disclosure as described herein. These components may be coupled (e.g., operatively, communicatively, functionally, electronically, electrically) via one or more interfaces.

The processor 702, the memory 704, the controller 706, or the transceiver 708, or various combinations or components thereof may be implemented in hardware (e.g., circuitry). The hardware may include a processor, a DSP, an ASIC, or other programmable logic device, or any combination thereof configured as or otherwise supporting a means for performing the functions described in the present disclosure.

The processor 702 may include an intelligent hardware device (e.g., a general-purpose processor, a DSP, a CPU, an ASIC, an FPGA, or any combination thereof). In some implementations, the processor 702 may be configured to operate the memory 704. In some other implementations, the memory 704 may be integrated into the processor 702. The processor 702 may be configured to execute computer-readable instructions stored in the memory 704 to cause the NE 700 to perform various functions of the present disclosure.

The memory 704 may include volatile or non-volatile memory. The memory 704 may store computer-readable, computer-executable code including instructions when executed by the processor 702 cause the NE 700 to perform various functions described herein. The code may be stored in a non-transitory computer-readable medium such as the memory 704 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 702 and the memory 704 coupled with the processor 702 may be configured to cause the NE 700 to perform one or more of the functions described herein (e.g., executing, by the processor 702, instructions stored in the memory 704). For example, the processor 702 may support wireless communication at the NE 700 in accordance with examples as disclosed herein. For example, the NE 700 may be configured to support means for performing the operations as described with respect to FIG. 4.

For example, the NE 700 may be configured to support: a means for transmitting, to a UE, a signaling configuring a first set of cells for multi-cell scheduling by a DCI format and CRC of the DCI format is scrambled by a C-RNTI or an MCS-C-RNTI of the UE; and a means for transmitting the DCI format to the UE, wherein the DCI format may indicate whether a set of fields in the DCI format is repurposed for indicating secondary cell dormancy for each secondary cell of the UE, and a first bit of the set of fields corresponds to a first secondary cell of the UE.

The controller 706 may manage input and output signals for the NE 700. The controller 706 may also manage peripherals not integrated into the NE 700. In some implementations, the controller 706 may utilize an operating system such as iOS®, ANDROID®, WINDOWS®, or other operating systems. In some implementations, the controller 706 may be implemented as part of the processor 702.

In some implementations, the NE 700 may include at least one transceiver 708. In some other implementations, the NE 700 may have more than one transceiver 708. The transceiver 708 may represent a wireless transceiver. The transceiver 708 may include one or more receiver chains 710, one or more transmitter chains 712, or a combination thereof.

A receiver chain 710 may be configured to receive signals (e.g., control information, data, or packets) over a wireless medium. For example, the receiver chain 710 may include one or more antennas for receive the signal over the air or wireless medium. The receiver chain 710 may include at least one amplifier (e.g., an LNA) configured to amplify the received signal. The receiver chain 710 may include at least one demodulator configured to demodulate the receive signal and obtain the transmitted data by reversing the modulation technique applied during transmission of the signal. The receiver chain 710 may include at least one decoder for decoding the processing the demodulated signal to receive the transmitted data.

A transmitter chain 712 may be configured to generate and transmit signals (e.g., control information, data, or packets). The transmitter chain 712may include at least one modulator for modulating data onto a carrier signal, preparing the signal for transmission over a wireless medium. The at least one modulator may be configured to support one or more techniques such as AM, FM, or digital modulation schemes like PSK or QAM. The transmitter chain 712 may also include at least one power amplifier configured to amplify the modulated signal to an appropriate power level suitable for transmission over the wireless medium. The transmitter chain 712 may also include one or more antennas for transmitting the amplified signal into the air or wireless medium.

It should be appreciated by persons skilled in the art that the components in exemplary NE 700 may be changed, for example, some of the components in exemplary NE 700 may be omitted or modified or a new component(s) may be added to exemplary NE 700, without departing from the spirit and scope of the disclosure. For example, in some embodiments, the NE 700 may not include the controller 706.

Those having ordinary skill in the art would understand that the operations or steps of the methods described in connection with the aspects disclosed herein may be embodied directly in hardware, in a software module executed by a processor, or in a combination of the two. A software module may reside in RAM memory, flash memory, ROM memory, EPROM memory, EEPROM memory, registers, a hard disk, a removable disk, a CD-ROM, or any other form of storage medium known in the art. Additionally, in some aspects, the operations or steps of the methods may reside as one or any combination or set of codes and/or instructions on a non-transitory computer-readable medium, which may be incorporated into a computer program product.

While this disclosure has been described with specific embodiments thereof, it is evident that many alternatives, modifications, and variations may be apparent to those skilled in the art. The disclosure is not limited to the examples and designs described herein but is to be accorded with the broadest scope consistent with the principles and novel features disclosed herein. For example, various components of the embodiments may be interchanged, added, or substituted in other embodiments. Also, all of the elements of each figure are not necessary for the operation of the disclosed embodiments. For example, one of ordinary skill in the art of the disclosed embodiments would be enabled to make and use the teachings of the disclosure by simply employing the elements of the independent claims. Accordingly, embodiments of the disclosure as set forth herein are intended to be illustrative, not limiting. Various changes may be made without departing from the spirit and scope of the disclosure.

In this document, the terms “includes,” “including,” or any other variation thereof, are intended to cover a non-exclusive inclusion, such that a process, method, article, or apparatus that includes a list of elements does not include only those elements but may include other elements not expressly listed or inherent to such process, method, article, or apparatus. An element proceeded by “a,” “an,” or the like does not, without more constraints, preclude the existence of additional identical elements in the process, method, article, or apparatus that includes the element. Also, the term “another” is defined as at least a second or more. The term “having” or the like, as used herein, is defined as “including.” Expressions such as “A and/or B” or “at least one of A and B” may include any and all combinations of words enumerated along with the expression. For instance, the expression “A and/or B” or “at least one of A and B” may include A, B, or both A and B. The wording “the first,” “the second” or the like is only used to clearly illustrate the embodiments of the present disclosure, but is not used to limit the substance of the present disclosure.

1. A user equipment (UE) for wireless communication, comprising:
at least one memory; and
at least one processor coupled with the at least one memory and configured to cause the UE to:
receive, from a base station (BS), a signaling configuring a first set of cells for multi-cell scheduling by a downlink control information (DCI) format and a cyclic redundancy check (CRC) of the DCI format is scrambled by a cell-radio network temporary identifier (C-RNTI) or a modulation and coding scheme C-RNTI (MCS-C-RNTI) of the UE;
receive the DCI format from the BS;
determine whether a set of fields in the DCI format is repurposed for indicating secondary cell dormancy for each secondary cell of the UE, wherein a first bit of the set of fields corresponds to a first secondary cell of the UE; and
switch to a dormant bandwidth part (BWP) of the first secondary cell of the UE in response to the first bit indicating the secondary cell dormancy for the first secondary cell.

2. The UE of claim 1, wherein the at least one processor is further configured to cause the UE to:
in response to: a one-shot hybrid automatic repeat request acknowledgement (HARQ-ACK) request field being absent from the DCI format or indicating that one-shot HARQ-ACK feedback is not triggered, a HARQ-ACK retransmission indicator being absent from the DCI format or indicating that HARQ-ACK retransmission is not triggered, and all frequency domain resource assignment (FDRA) fields in the DCI format indicate an invalid value, determine that the set of fields in the DCI format is repurposed for indicating the secondary cell dormancy for each secondary cell of the UE.

3. The UE of claim 1, wherein the DCI comprises a first indicator indicating whether the set of fields in the DCI format is repurposed for indicating the secondary cell dormancy for each secondary cell of the UE, or a second indicator in the DCI format is used for indicating the secondary cell dormancy for each secondary cell group of the UE.

4. The UE of claim 3, wherein, when the first indicator indicates the set of fields in the DCI format are repurposed for indicating the secondary cell dormancy for each secondary cell of the UE, the DCI format does not schedule any data transmission; or
when the first indicator indicates the second indicator in the DCI format is used for indicating the secondary cell dormancy for each secondary cell group of the UE, the DCI format schedules one or more data transmissions for the UE.

5. The UE of claim 4, wherein the set of fields comprises one or more frequency domain resource assignment (FDRA) fields corresponding to one or more cells with smallest serving cell indices among a second set of cells, and
wherein the second set of cells is indicated by the DCI format among the first set of cells in response to the DCI format including an indicator indicating scheduled cells, otherwise the second set of cells is the first set of cells.

6. The UE of claim 1, wherein the first set of cells comprises a primary cell of the UE, and wherein the at least one processor is further configured to cause the UE to:
in response to a one-shot hybrid automatic repeat request acknowledgement (HARQ-ACK) request field being absent from the DCI format or indicating that one-shot HARQ-ACK feedback is not triggered, a HARQ-ACK retransmission indicator being absent from the DCI format or indicating that HARQ-ACK retransmission is not triggered, and all frequency domain resource assignment (FDRA) fields in the DCI format, except a FDRA field for the primary cell, indicate an invalid value, determine that the set of fields in the DCI format is repurposed for indicating the secondary cell dormancy for each secondary cell of the UE.

7. The UE of claim 1, wherein the at least one processor is further configured to cause the UE to:
in response to a one-shot hybrid automatic repeat request acknowledgement (HARQ-ACK) request field being absent from the DCI format or indicating that one-shot HARQ-ACK feedback is not triggered, a HARQ-ACK retransmission indicator being absent from the DCI format or indicating that HARQ-ACK retransmission is not triggered, and at least one frequency domain resource assignment (FDRA) field in the DCI format indicates an invalid value, determine that the set of fields in the DCI format is repurposed for indicating the secondary cell dormancy for each secondary cell of the UE.

8. The UE of claim 1, wherein the set of fields is specifically used for a cell with a smallest serving cell index among one or more cells within a second set of cells with corresponding frequency domain resource assignment (FDRA) fields in the DCI format indicates an invalid value; and
wherein the second set of cells is indicated by the DCI format among the first set of cells in response to the DCI format including an indicator indicating scheduled cells, otherwise the second set of cells is the first set of cells.

9. The UE of claim 1, wherein the set of fields are concatenated into a bitmap based indicator according to a predefined rule, and each secondary cell of the UE corresponds to a respective bit in the bitmap based indicator.

10. The UE of claim 1, wherein a first value of the first bit indicates the UE to switch to the dormant BWP of the first secondary cell; and
wherein a second value of the first bit indicates the UE to switch to a first active BWP of the first secondary cell when a current active BWP of the first secondary cell is the dormant BWP or indicates to the UE to maintain the current active BWP of the first secondary cell when the current active BWP of the first secondary cell is not the dormant BWP.

11. The UE of claim 1, wherein the set of fields comprises:
a cell-specific field with a non-configurable field size;
a cell-specific field with a configurable field size; or a cell-common field.

12. A base station (BS) for wireless communication, comprising:
at least one memory; and
at least one processor coupled with the at least one memory and configured to cause the BS to:
transmit, to a user equipment (UE), a signaling configuring a first set of cells for multi-cell scheduling by a downlink control information (DCI) format and a cyclic redundancy check (CRC) of the DCI format is scrambled by a cell-radio network temporary identifier (C-RNTI) or a modulation and coding scheme C-RNTI (MCS-C-RNTI) of the UE; and
transmit the DCI format to the UE, wherein the DCI format indicates whether a set of fields in the DCI format is repurposed for indicating secondary cell dormancy for each secondary cell of the UE, and a first bit of the set of fields corresponds to a first secondary cell of the UE.

13. The BS of claim 12, wherein, when a one-shot hybrid automatic repeat request acknowledgement (HARQ-ACK) request field is absent from the DCI format or indicates that one-shot HARQ-ACK feedback is not triggered, a HARQ-ACK retransmission indicator is absent from the DCI format or indicates that HARQ-ACK retransmission is not triggered, and all frequency domain resource assignment (FDRA) fields in the DCI format indicate an invalid value, the set of fields in the DCI format is repurposed for indicating the secondary cell dormancy for each secondary cell of the UE.

14. The BS of claim 12, wherein the DCI comprises a first indicator indicating whether the set of fields in the DCI format is repurposed for indicating the secondary cell dormancy for each secondary cell of the UE, or a second indicator in the DCI format is used for indicating the secondary cell dormancy for each secondary cell group of the UE.

15. The BS of claim 14, wherein, when the first indicator indicates that the set of fields in the DCI format is repurposed for indicating the secondary cell dormancy for each secondary cell of the UE, the DCI format does not schedule any data transmission; or
when the first indicator indicates that the second indicator in the DCI format is used for indicating the secondary cell dormancy for each secondary cell group of the UE, the DCI format schedules one or more data transmissions for the UE.

16. The BS of claim 12, wherein the first set of cells comprises a primary cell of the UE; and
wherein, when a one-shot hybrid automatic repeat request acknowledgement (HARQ-ACK) request field is absent from the DCI format or indicates that one-shot HARQ-ACK feedback is not triggered, a HARQ-ACK retransmission indicator is absent from the DCI format or indicates that HARQ-ACK retransmission is not triggered, and all frequency domain resource assignment (FDRA) fields in the DCI format, except a FDRA field for the primary cell, indicate an invalid value, the set of fields in the DCI format is repurposed for indicating the secondary cell dormancy for each secondary cell of the UE.

17. The BS of claim 12, wherein, when a one-shot hybrid automatic repeat request acknowledgement (HARQ-ACK) request field is absent from the DCI format or indicates that one-shot HARQ-ACK feedback is not triggered, a HARQ-ACK retransmission indicator is absent from the DCI format or indicates that HARQ-ACK retransmission is not triggered, and at least one frequency domain resource assignment (FDRA) field in the DCI format indicates an invalid value, the set of fields in the DCI format is repurposed for indicating the secondary cell dormancy for each secondary cell of the UE.

18. The BS of claim 12, wherein the set of fields is specifically used for a cell with a smallest serving cell index among one or more cells within a second set of cells with corresponding FDRA fields in the DCI format indicating an invalid value; and
wherein the second set of cells is indicated by the DCI format among the first set of cells in response to the DCI format including an indicator indicating scheduled cells, otherwise the second set of cells is the first set of cells.

19. A processor for wireless communication, comprising:
at least one controller coupled with at least one memory and configured to cause the processor to:
receive, from a base station (BS), a signaling configuring a first set of cells for multi-cell scheduling by a downlink control information (DCI) format and a cyclic redundancy check (CRC) of the DCI format is scrambled by a cell-radio network temporary identifier (C-RNTI) or a modulation and coding scheme C-RNTI (MCS-C-RNTI) of a user equipment (UE);
receive the DCI format from the BS;
determine whether a set of fields in the DCI format is repurposed for indicating secondary cell dormancy for each secondary cell of the UE, wherein a first bit of the set of fields corresponds to a first secondary cell of the UE; and
switch to a dormant bandwidth part (BWP) of the first secondary cell of the UE in response to the first bit indicating the secondary cell dormancy for the first secondary cell.

20. A method performed by a user equipment (UE), the method comprising:
receiving, from a base station (BS), a signaling configuring a first set of cells for multi-cell scheduling by a downlink control information (DCI) format and a cyclic redundancy check (CRC) of the DCI format is scrambled by a cell-radio network temporary identifier (C-RNTI) or a modulation and coding scheme C-RNTI (MCS-C-RNTI) of a user equipment (UE);
receiving the DCI format from the BS;
determining whether a set of fields in the DCI format is repurposed for indicating secondary cell dormancy for each secondary cell of the UE, wherein a first bit of the set of fields corresponds to a first secondary cell of the UE; and
switching to a dormant bandwidth part (BWP) of the first secondary cell of the UE in response to the first bit indicating the secondary cell dormancy for the first secondary cell.
